(19) United States
(12) Patent Application Publication
(10) Pub. No.: US 2008/0311515 A1
(43) Pub. Date: Dec. 18, 2008

(54) POSITIVE RESIST COMPOSITION AND METHOD OF FORMING RESIST PATTERN

(75) Inventors: Takeyoshi Mimura, Kawasaki-shi (JP); Takako Suzuki, Kawasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: TOKYO OHKA KOGYO CO., LTD., Kawasaki-shi (JP)

(21) Appl. No.: 12/136,391

(22) Filed: Jun. 10, 2008

(30) Foreign Application Priority Data
Jun. 12, 2007 (JP) 2007-155420
Jun. 12, 2007 (JP) 2007-155421

(51) Int. Cl. G03F 7/039; G03F 7/20

(52) U.S. Cl. 430/285.1; 430/325

(57) ABSTRACT

A positive resist composition including a resin component (A) which exhibits increased solubility in an alkali developing solution under action of acid and an acid-generator component (B) which generates acid upon irradiation, the resin component (A) including a structural unit (a1) derived from hydroxystyrene and a structural unit (a2) having an acetal-type acid dissociable, dissolution inhibiting group, and the acid-generator component (B) including an acid generator (B1) consisting of a compound represented by general formula (b1-1) (wherein Z represents a hydrogen atom or a group represented by general formula (b1-1-1); R⁴⁰¹ represents an acid dissociable group; R⁴¹, R⁴² and R⁴³ each independently represents a halogen atom, a halogenated alkyl group, an alkyl group, an acetyl group, an alkoxy group, a carboxy group or a hydroxyalkyl group; and X⁻ represents an anion) or an acid generator (B1′) consisting of a compound represented by general formula (b1-1′).

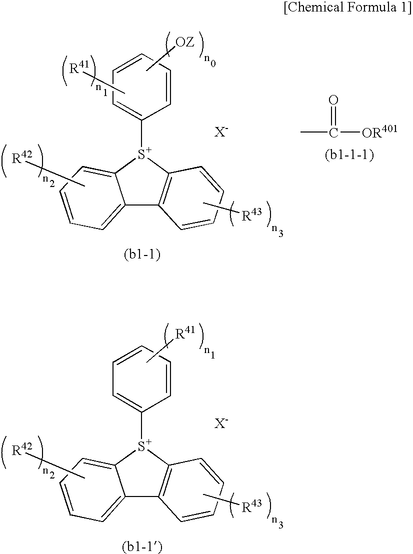

### TECHNICAL FIELD

The present invention relates to a positive resist composition and a method of forming a resist pattern.

Priority is claimed on Japanese Patent Application No. 2007-155420, filed Jun. 12, 2007, and Japanese Patent Application No. 2007-155421, filed Jun. 12, 2007, the contents of which are incorporated herein by reference.

### BACKGROUND ART

In lithography techniques, for example, a resist film composed of a resist material is formed on a substrate, and the resist film is subjected to selective exposure of radial rays such as light or electron beam through a mask having a predetermined pattern, followed by development, thereby forming a resist pattern having a predetermined shape on the resist film. A resist material in which the exposed portions become soluble in a developing solution is called a positive-type, and a resist material in which the exposed portions become insoluble in a developing solution is called a negative-type.

In recent years, in the production of semiconductor elements and liquid crystal display elements, advances in lithography techniques have lead to rapid progress in the field of pattern miniaturization.

Typically, these miniaturization techniques involve shortening the wavelength of the exposure light source. Conventionally, ultraviolet radiation typified by g-line and i-line radiation has been used, but nowadays KrF excimer lasers and ArF excimer lasers are now starting to be introduced in mass production. Furthermore, research is also being conducted into lithography techniques that use exposure light source having a wavelength shorter than these excimer lasers, such as F₂ excimer lasers, electron beam (EB), extreme ultraviolet radiation (EUV), and X ray.

Resist materials for use with these types of exposure light sources require lithography properties such as a high resolution capable of reproducing patterns of minute dimensions, and a high level of sensitivity to these types of exposure light sources. As a resist material which satisfies these conditions; a chemically amplified resist is used, which includes a base resin that exhibits a changed solubility in an alkali developing solution under action of acid and an acid generator that generates acid upon exposure. For example, a chemically amplified positive resist contains, as a base resin, a resin which exhibits increased solubility in an alkali developing solution under action of acid, and an acid generator. In the formation of a resist pattern, when acid is generated from the acid generator upon exposure, the exposed portions become soluble in an alkali developing solution.

Until recently, polyhydroxystyrene (PHS) or derivative resins thereof in which the hydroxyl groups are protected with acid-dissociable, dissolution-inhibiting groups (PHS-based resins), which exhibit high transparency to a KrF excimer laser (249 nm), have been used as the base resin component of chemically amplified resists. However, because PHS-based resins contain aromatic rings such as benzene rings, their transparency is inadequate for light with wavelengths shorter than 248 nm, such as light of 193 nm. Accordingly, chemically amplified resists that use a PHS-based resin as the base resin component suffer from low levels of resolution in processes that use light of 193 nm.

As a result, resins that contain structural units derived from (meth)acrylate esters within the main chain (acrylic resins) are now widely used as base resins for resists that use ArF excimer laser lithography, as they exhibit excellent transparency in the vicinity of 193 nm. In the case of a positive resist, as the base resin, those which have a structural unit derived from (meth)acrylate ester including an aliphatic polycyclic group-containing, tertiary alkyl ester-type acid dissociable, dissolution inhibiting group, such as a structural unit derived from 2-alkyl-2-adamantyl(meth)acrylate are mainly used (for example, see Patent Document 1),

Here, the term “(meth)acrylate ester” is a generic term that includes either or both of the acrylate ester having a hydrogen atom bonded to the α-position and the methacrylate ester having a methyl group bonded to the α-position. The term “(meth)acrylate” is a generic term that includes either or both of the acrylate having a hydrogen atom bonded to the α-position and the methacrylate having a methyl group bonded to the α-position. The term “(meth)acrylic acid” is a generic term that includes either or both of acrylic acid having a hydrogen atom bonded to the α-position and methacrylic acid having a methyl group bonded to the α-position.

On the other hand, as acid generators usable in a chemically amplified resist, various types have been proposed including, for example, onium salt-based acid generators such as iodonium salts and sulfonium salts; oxime sulfonate-based acid generators; diazomethane-based acid generators; nitrobenzylsulfonate-based acid generators; iminosulfonate-based acid generators; and disulfone-based acid generators. Currently, as acid generators, those which include a triphenylsulfonium skeleton, dinaphthyl monophenylsulfonium skeleton, or the like are used (for example, see Patent Document 2).

[Patent Document 1] Japanese Unexamined Patent Application, First Publication No. 2003-241385

[Patent Document 2] Japanese Unexamined Patent Application, First Publication No. 2005-37888

### Disclosure of Invention

In recent years, as requirements for high resolution increase with progress in the miniaturization of resist patterns, improvement in the shape of pattern and various lithography properties has been demanded.

For example, in electron beam (EB) or extreme ultraviolet (EUV) lithography, formation of an extremely fine pattern of several tens of nanometers is a goal. As the pattern size becomes smaller, it becomes extremely important to form a pattern having an excellent shape. Further, in conventional chemically amplified positive resist compositions, further improvement in resolution has been demanded.

However, when a conventional chemically amplified positive resist composition was used in formation of a resist pattern using EB or EUV as the exposure source, the shape of the resist pattern formed was unsatisfactory.

The present invention takes the above circumstances into consideration, with an object of providing a positive resist composition exhibiting an excellent resolution, which contains a novel compound preferable as an acid generator for a resist composition, and a method of forming a resist pattern using the positive resist composition.

### Means to Solve the Problems

As a result of extensive and intensive studies, the present inventors found that the above-mentioned problems can be solved by using a resin component containing two specific structural units as the base component, and an acid generator having a specific cation moiety. The present invention has been completed based on this finding.

Specifically, a first aspect of the present invention is a positive resist composition including a resin component (A) which exhibits increased solubility in an alkali developing solution under action of acid and an acid-generator component (B) which generates acid upon exposure, the resin component (A) including a structural unit (a1) derived from hydroxystyrene and a structural unit (a2) represented by general formula (a2-l) or (a2-2) shown below, and the acid-generator component (B) including an acid generator (B1) consisting of a compound represented by general formula (b1-1) shown below or an acid generator (B1′) consisting of a compound represented by general formula (b1-1′) shown below:

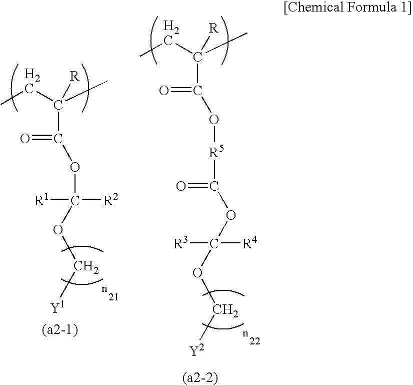

wherein in general formula (a2-1), R represents a hydrogen atom, a lower alkyl group of 1 to 5 carbon atoms or a halogenated lower alkyl group; R¹ and R² each independently represents a hydrogen atom or a lower alkyl group of 1 to 5 carbon atoms; Y¹ represents a lower alkyl group of 1 to 5 carbon atoms or a monovalent aliphatic cyclic group; and n₂₁ represents an integer of 0 to 3; and in general formula (a2-2), R is as defined above; R³ and R⁴ each independently represents a hydrogen atom or a lower alkyl group of 1 to 5 carbon atoms; R⁵ represents an alkylene group or a divalent aliphatic cyclic group; Y²represents a lower alkyl group of 1 to 5 carbon atoms or a monovalent aliphatic cyclic group; and n₂₂ represents an integer of 0 to 3;

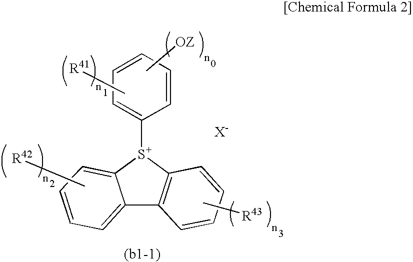

wherein Z represents a hydrogen, atom or a group represented by general formula (b1-1-1) shown below; R⁴¹, R⁴² and R⁴³ each independently represents a halogen atom, a halogenated alkyl group, an alkyl group, an acetyl group, an alkoxy group, a carboxy group or a hydroxyalkyl group; no represents an integer of 1 to 3, and n₁ to n₃ each independently represents an integer of 0 to 3, with the proviso that n₀+n₁ is 5 or less; and X⁻ represents an anion;

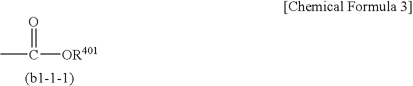

wherein R⁴⁰¹ represents an acid dissociable group; and

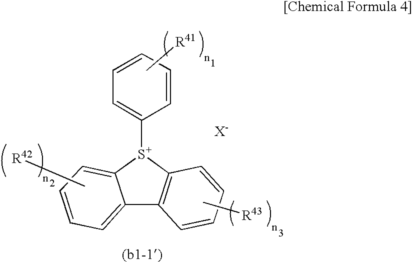

wherein R⁴¹, R⁴² and R⁴³ each independently represents a halogen atom, a halogenated alkyl group, an alkyl group, an acetyl group, an alkoxy group, a carboxy group or a hydroxyalkyl group; n₁, n₂ and n₃ each independently represents an integer of 0 to 3; and X⁻ represents an anion.

Further, a second aspect of the present invention is a method of forming a resist pattern, including: applying a resist composition according to the first aspect of the present invention to a substrate to form a resist film on the substrate; conducting exposure of the resist film; and alkali-developing the resist film to form a resist pattern.

In the present description and claims, the term “structural unit” refers to a monomer unit that contributes to the formation of a resin component (polymer, copolymer).

An “alkyl group” includes linear, branched or cyclic, monovalent saturated hydrocarbon, unless otherwise specified.

A “lower alkyl group” is an alkyl group of 1 to 5 carbon atoms.

The term “exposure” is used as a general concept that includes irradiation with any form of radiation.

### Effect of the Invention

According to the present invention, there are provided a positive resist composition exhibiting an excellent resolution, which contains a novel compound preferable as an acid generator for a resist composition, and a method of forming a resist pattern using the positive resist composition.

### BEST MODE FOR CARRYING OUT THE INVENTION

<<Positive Resist Composition>>

The positive resist composition of the present invention includes a resin component (A) (hereafter, frequently referred to as “component (A)”) which exhibits increased solubility in an alkali developing solution under action of acid and an acid-generator component (B) which generates acid upon exposure.

In the positive resist composition of the present invention, the component (A) is insoluble in an alkali developing solution prior to exposure, and when acid is generated from the component (B) upon exposure, the solubility of the entire component (A) in an alkali developing solution increases, and hence, the component (A) changes from alkali insoluble to alkali soluble. Therefore, in the formation of a resist pattern, by conducting selective exposure of a resist film formed using the positive resist composition, the exposed portions become alkali soluble, whereas the unexposed portions remain alkali insoluble, and hence, a resist pattern can be formed by alkali developing.

<Component (A)>

In the present invention, the component (A) includes a structural unit (a1) derived from hydroxystyrene and a structural unit (a2) represented by general formula (a24) or (a2-2) shown above.

[Structural unit (a1)]

The structural unit (a1) is a structural unit derived from hydroxystyrene. By using the component (A) including the structural unit (a1) and the structural unit (a2) explained below in combination with the acid generator (B1) explained below, a resist pattern exhibiting excellent resolution or excellent shape can be formed. Further, by virtue of the component (A) including the structural unit (a1), the dry etching resistance is improved. Furthermore, the structural unit (a1) is advantageous in that hydroxystyrene as a raw material is easily available at a low cost.

In the present description and claims, the term “hydroxystyrene” is a general concept which includes hydroxystyrene, hydroxystyrene in which the hydrogen atom on the α-position thereof has been substituted with a substituent such as an alkyl group, and derivatives thereof.

The α-position (the carbon on the α-position) of hydroxystyrene refers to the carbon atom bonded to the benzene ring, unless otherwise specified.

The term “structural unit derived from hydroxystyrene” refers to a structural unit which is formed by the cleavage of the ethylenic double bond of hydroxystyrene.

As a preferable example of the structural unit (a1), a structural unit represented by general formula (a1-1) shown below can be exemplified.

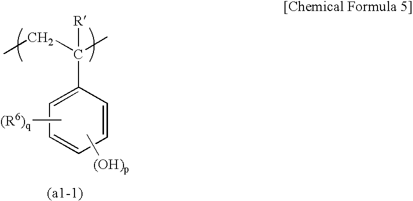

wherein R′ represents a hydrogen atom or a lower alkyl group; R⁶ represents a lower alkyl group; p represents an integer of 1 to 3; and q represents an integer of 0 to 2.

In general formula (a1-1) above, the lower alkyl group for R′ is an alkyl group of 1 to 5 carbon atoms, and specific examples thereof include linear or branched alkyl groups such as a methyl group, ethyl group, propyl group, isopropyl group, n-butyl group, isobutyl group, tert-butyl group, pentyl group, isopentyl group and neopentyl group. Among these, a methyl group is preferable.

As R′, a hydrogen atom or a methyl group is particularly desirable.

p is an integer of 1 to 3, and is preferably 1.

The bonding position of the hydroxyl group may be either the o-position, m-position or p-position, of the phenyl group. When p is 1, the bonding position of the hydroxyl group is preferably the p-position, in terms of availability at a low cost. When p is 2 or 3, a desired combination of the bonding positions can be used.

q is an integer of 0 to 2, and is preferably 0 or 1. It is particularly desirable that q be 0 industrially.

As the lower alkyl group for R⁶, the same as the lower alkyl group for R′ can be exemplified.

When q is 1, the substitution position of R⁶ may be either the o-position, m-position or p-position. When q is 2, a desired combination of the substitution positions can be used. Further, when q is 2, the plurality of R⁶ may the same or different.

As the structural unit (a1), one type of structural unit may be used, or two or more types may be used in combination.

In the component (A), the amount of the structural unit (a1) based on the combined total of all structural units constituting the component (A) is preferably 50 to 90 mol %, more preferably 55 to 85 mol %, and still more preferably 60 to 80 mol %. When the amount of the structural unit (a1) is within the above-mentioned range, a suitable alkali solubility can be obtained, and a good balance can be achieved with the other structural units.

[Structural unit (a2)]

The structural unit (a2) is a structural unit represented by general formula (a2-1) or (a2-2) shown above. By using the component (A) including the structural unit (a1) and the structural unit (a2) in combination with the acid generator (B1) explained below, a resist pattern exhibiting excellent resolution or excellent shape can be formed.

Hereafter, the structural unit represented by general formula (a2-1) is referred to as “structural unit (a2-1)”, and the structural unit represented by general formula (a2-2) is referred to as “structural unit (a2-2)”.

The group represented by formula —C(R¹)(R²—0—CH₂)ₙ₂₁—Y¹ in general formula (a2-1) and the group represented by the formula —C(R³)(R⁴)—O—(CH₂)ₙ₂₂—Y² in general formula (a2-2) are the so-called acetal-type acid dissociable, dissolution inhibiting groups.

The Structural unit (a2-1) and the structural unit (a2-2) are common in that they both have a structure in which the acetal-type acid dissociable, dissolution inhibiting group is bonded to the terminal oxygen atom of the carbonyloxy group (—C(O)—O—). In this structure, when acid is generated from the component (B) upon exposure, the linkage between the acid dissociable, dissolution inhibiting group and the terminal oxygen atom of the carbonyloxy group is cleaved by the action of acid.

In the present description and claims, the expression “acid dissociable” refers to the capability of dissociating from the component (A) by the action of acid generated from the component (B) upon exposure.

The term “dissolution inhibiting group” refers to a group which exhibits the alkali-insolubility to render the entire component (A) insoluble in an alkali developing solution prior to dissociation, and also causes the entire component (A) to become soluble in an alkali developing solution following dissociation.

Thus, the component (A) containing the structural unit (a2) is insoluble in an alkali developing solution prior to exposure, and when acid generated from the component (B) upon exposure acts on the component (A), the acetal-type acid dissociable, dissolution inhibiting groups dissociate, thereby increasing the solubility of the entire component (A) in an alkali developing solution. As a result, the entire component (A) changes from alkali insoluble to alkali soluble. Therefore, in the formation of a resist pattern, by conducting selective exposure of a resist film formed by using the positive resist composition, the exposed portions become alkali soluble, whereas the unexposed portions remain alkali-insoluble, and hence, a resist pattern can be formed by alkali developing.

In general formula (a2-1)f R represents a hydrogen atom, a lower alkyl group of 1 to 5 carbon atoms or a halogenated lower alkyl group. As the lower alkyl group for R, the same as the lower alkyl group for R′ in general formula (a1-1) above may be exemplified.

As R, a hydrogen atom, a lower alkyl group or a fluorinated lower alkyl group is preferable. In terms of industrial availability, it is particularly desirable that R be a hydrogen atom or a methyl group.

R¹ and R² each independently represents a hydrogen atom or a lower alkyl group of 1 to 5 carbon atoms. As the lower alkyl group for R¹ and R², the same as the lower alkyl group for R′ in general formula (a1-1) above may be exemplified. In terms of industrial availability, it is preferable that R¹ and R² each independently represents a methyl group or an ethyl group.

In terms of improving the effects of the present invention, it is preferable that at least one of R¹ and R² be a hydrogen atom, and it is more preferable that both of R¹ and R² be hydrogen atoms.

n₂₁ represents an integer of 0 to 3, preferably 0 or 1, and most preferably 0.

Y¹ represents a lower alkyl group of 1 to 5 carbon atoms or a monovalent aliphatic cyclic group.

As the lower alkyl group for Y¹, the same as the lower alkyl group for R′ in general formula (a1-1) above may be exemplified.

As the monovalent aliphatic cyclic group for Y¹, any one can be selected appropriately from the multitude of aliphatic monocyclic groups and aliphatic polycyclic groups that have been proposed for the resins of resist compositions designed for use with ArF excimer lasers.

In the present description and claims, the term “aliphatic cyclic group” refers to a monocyclic group or polycyclic group that has no aromaticity.

The “aliphatic cyclic group” for Y¹ may or may not have a substituent.

Examples of substituents include lower alkyl groups of 1 to 5 carbon atoms, fluorine atom, fluorinated lower alkyl groups of 1 to 5 carbon atoms, and hydrophilic groups. Examples of hydrophilic groups include ═O, —COOR″ (wherein R″ represents an alkyl group), an alcoholic hydroxyl group, —OR″ (wherein R″ represents an alkyl group), an imino group and an amino group. In terms of availability, ═O or an alcoholic hydroxyl group is preferable.

The basic ring of the “aliphatic cyclic group” exclusive of substituents may be a ring constituted from only carbon and hydrogen (hydrocarbon ring). Alternatively, the basic ring may be a hetero atom in which a part of the carbon atoms constituting a hydrocarbon ring is substituted with hetero atoms such as an oxygen atom, a sulfur atom, and a nitrogen atom. In terms of achieving the effects of the present invention, it is preferable that the basic ring of Y¹ be a hydrocarbon ring.

As the hydrocarbon ring, any one can be selected appropriately from those that have been proposed for the resins of resist compositions designed for use with ArF excimer lasers and KrF excimer lasers. Specific examples thereof include monocycloalkanes and polycycloalkanes such as bicycloalkanes, tricycloalkanes and tetracycloalkanes. Examples of monocycloalkanes include cyclopentane and cyclohexane. Examples of polycycloalkanes include adamantane, norbornane, norbornene, methylnorbornane, ethylnorbornane, methylnorbornene, ethylnorbornene, isobornane, tricyclodecane and tetracyclododecane. Among these, cyclopentane, cyclohexane, adamantane, norbornane, norbornene, methylnorbornane, ethylnorbornane, methylnorbornene, ethylnorbornene and tetracyclododecane are preferable industrially, and adamantane is more preferable.

As preferable examples of groups represented by formula —C(R¹)(R²)—O—(CH₂)ₙ₂₁—Y¹, those represented by formulas (11) to (22) may be exemplified.

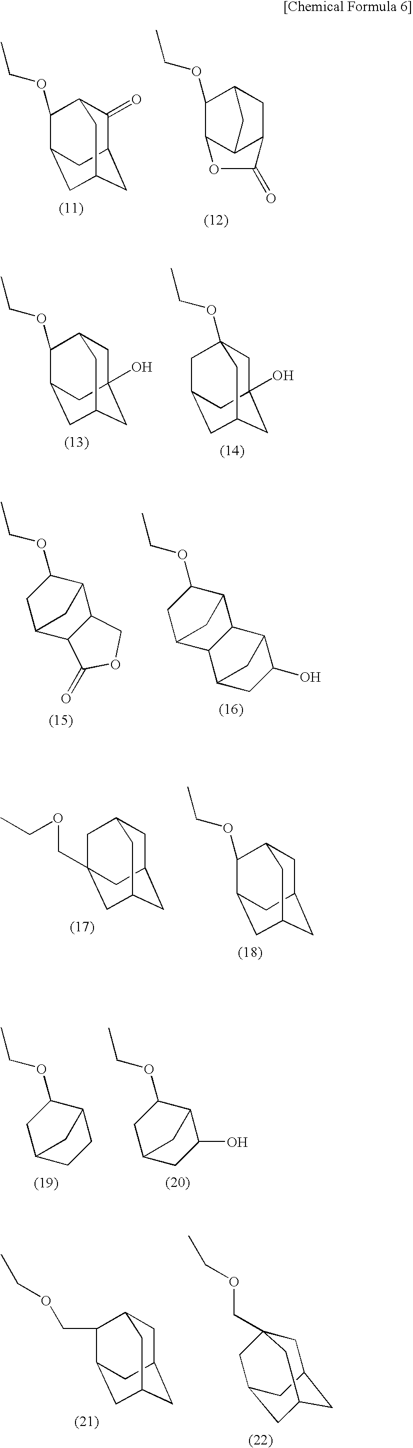

In general formula (a2-2), R is as defined above, R³ and R⁴ each independently represents a hydrogen atom or a lower alkyl group of 1 to 5 carbon atoms, Y² represents a lower alkyl group of 1 to 5 carbon atoms or a monovalent aliphatic cyclic group, and n₂₂ represents an integer of 0 to 3.

As R, R³, R⁴, n₂₂ and Y², the same as R, R¹, R², n₂₁ and Y¹ in general formula (a2-1) may be exemplified.

R³ represents an alkylene group or a divalent aliphatic cyclic group.

When R⁵ is an alkylene group, it preferably has 1 to 10 carbon atoms, more preferably 1 to 6, still more preferably 1 to 4, and most preferably 1 to 3.

When R⁵ is an aliphatic cyclic group, it may or may not have a substituent Examples of substituents include lower alkyl groups of 1 to 5 carbon atoms, fluorine atom, fluorinated lower alkyl groups of 1 to 5 carbon atoms, and oxygen atom (═O).

The basic ring of the aliphatic cyclic group for R⁵ exclusive of substituents is not limited to be constituted from only carbon and hydrogen (not limited to hydrocarbon groups), but is preferably a hydrocarbon group. Further, the “hydrocarbon group” may be either saturated or unsaturated, but is preferably saturated. Furthermore, the aliphatic cyclic group for R⁵ is preferably a polycyclic group.

As such aliphatic cyclic groups for R⁵, groups in which two or more hydrogen atoms have been removed from a monocycloalkane or a polycycloalkane such as a bicycloalkane, tricycloalkane or tetracycloalkane, which may or may not be substituted with a lower alkyl group, a fluorine atom or a fluorinated lower alkyl group, may be exemplified. Specific examples include groups in which two or more hydrogen atoms have been removed from a monocycloalkane such as cyclopentane and cyclohexane; and groups in which two or more hydrogen atoms have been removed from a polycycloalkane such as adamantane, norbornane, isobornane, tricyclodecane or tetracyclododecane.

As the aliphatic cyclic group for R⁵, a group represented by general formula (y-1) shown below is particularly desirable.

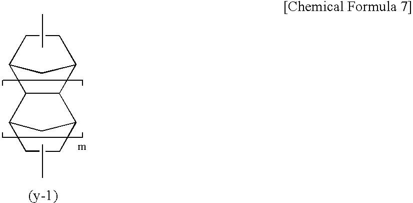

wherein m is 0 or 1, and preferably 1.

Specific examples of structural unit (a2-1) represented by general formula (a2-1) include structural units represented by formulas (a1-2-1) to (a1-2-39).

Specific examples of structural unit (a2-2) represented by general formula (a2-2) include structural units represented by formulas (a1-4-1) to (a1-4-42).

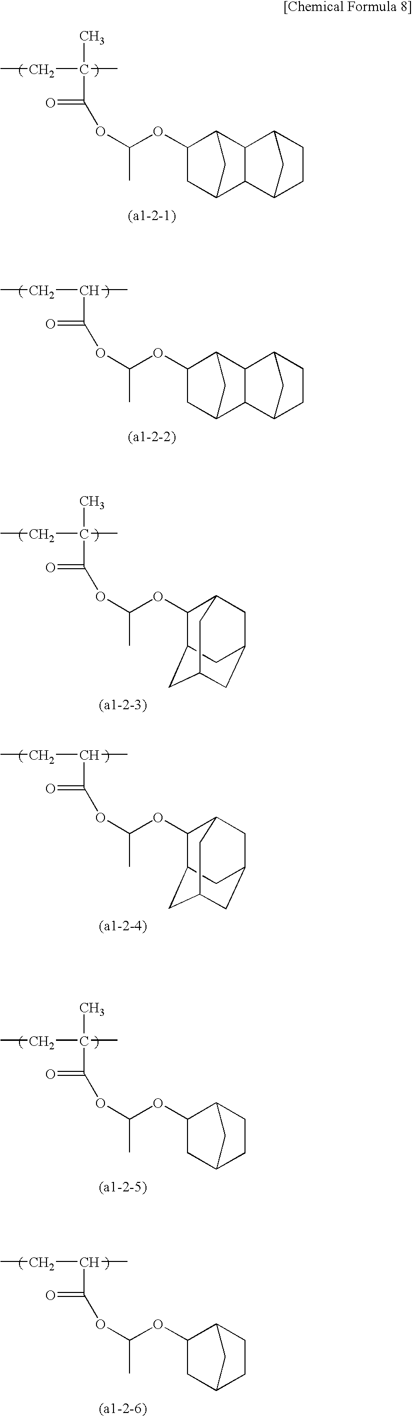

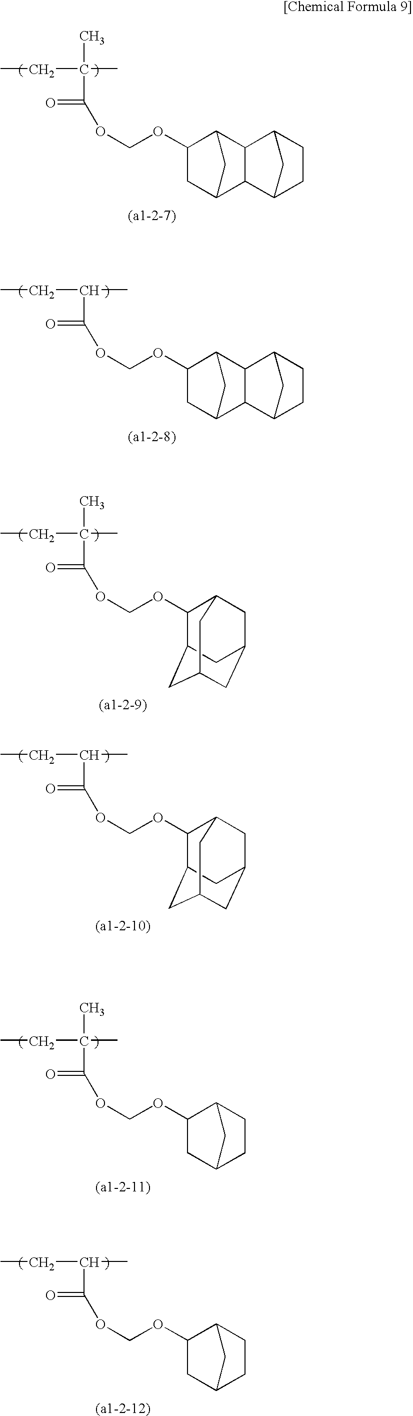

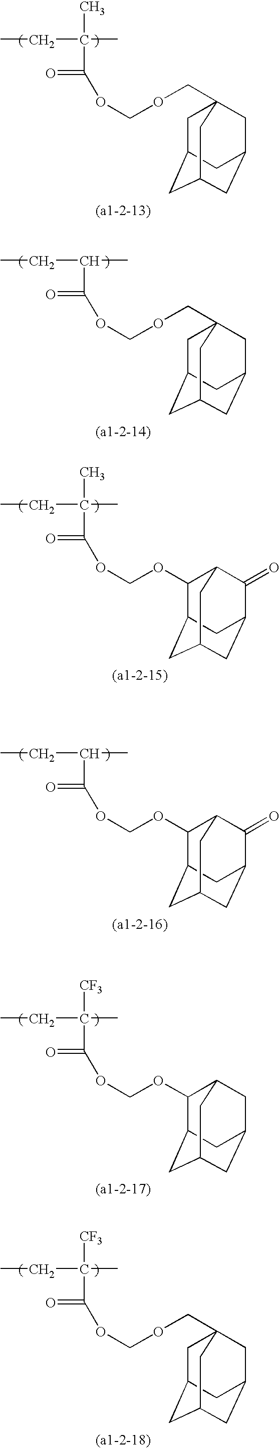

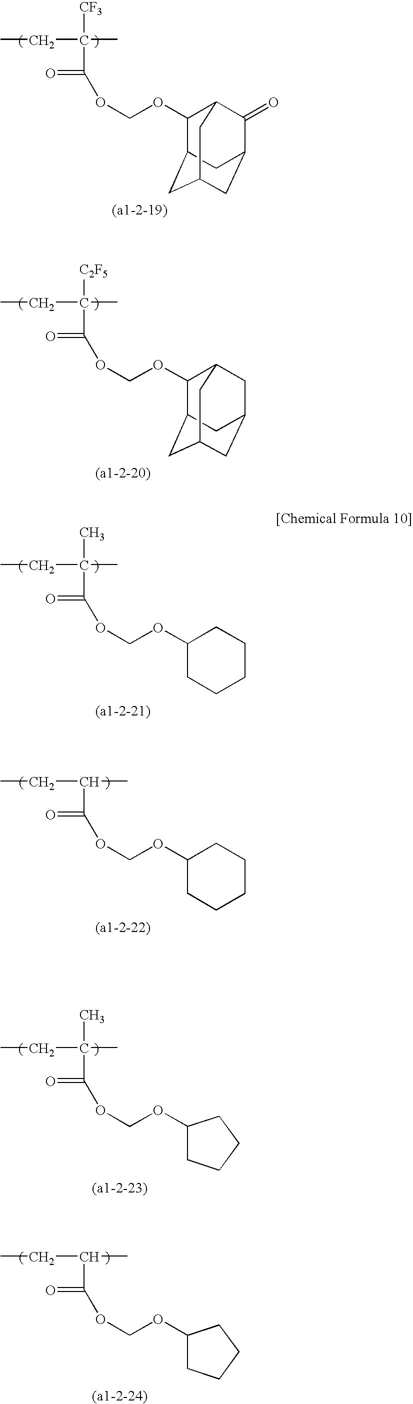

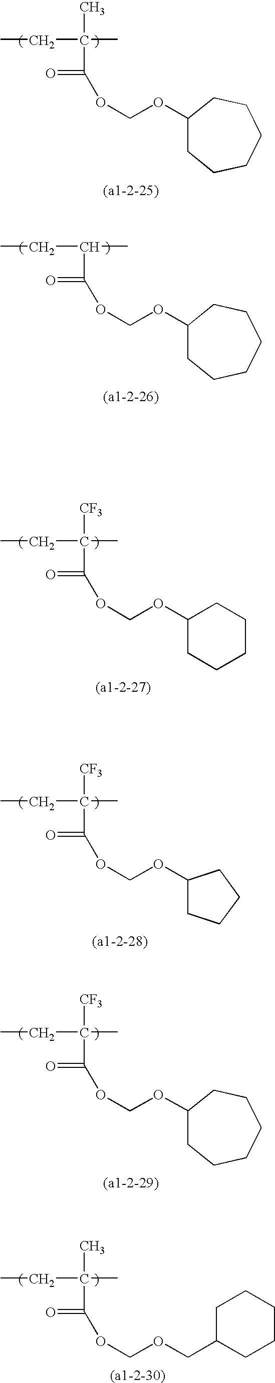

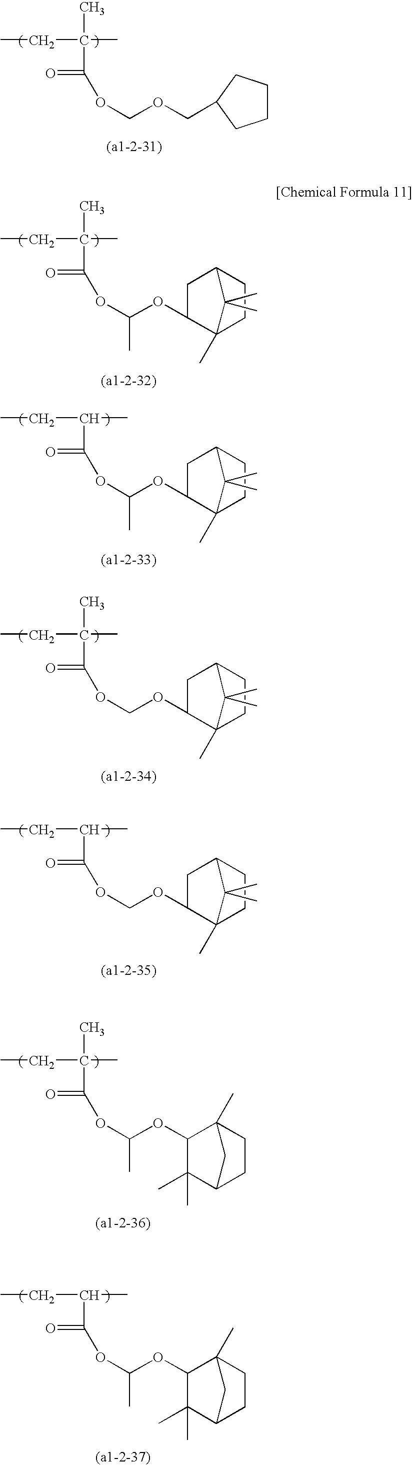

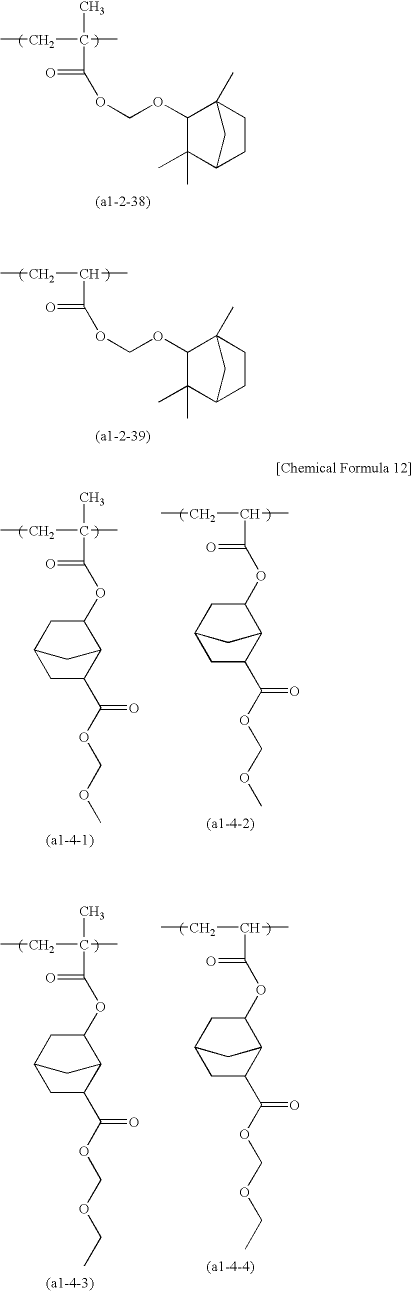

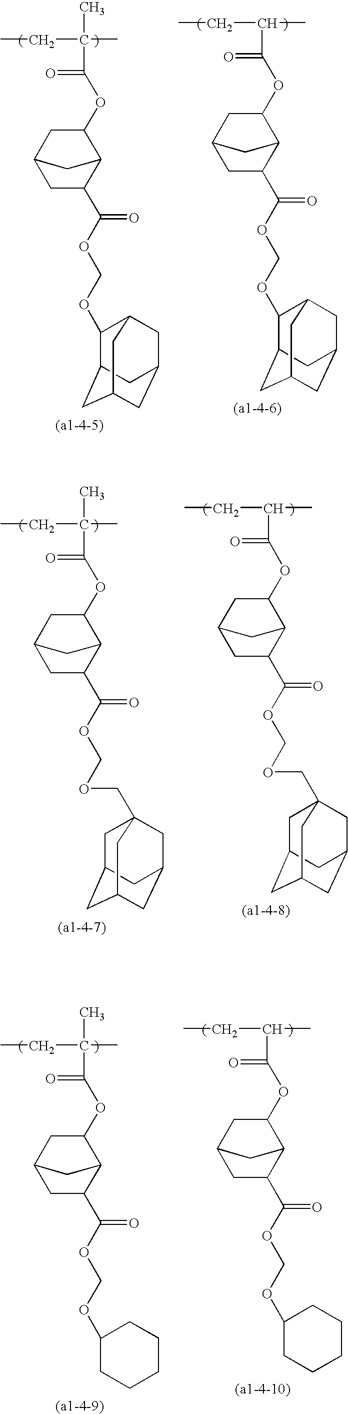

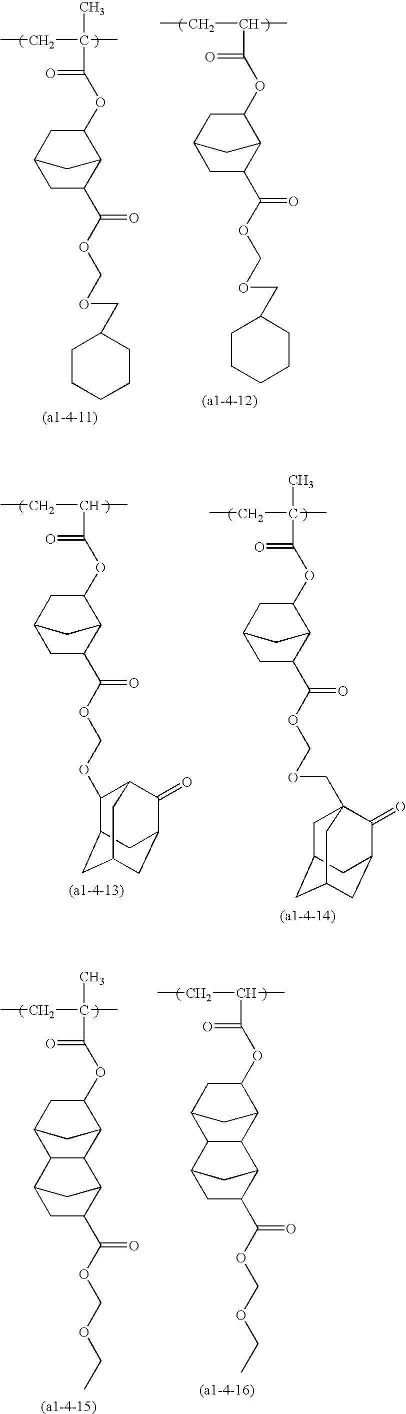

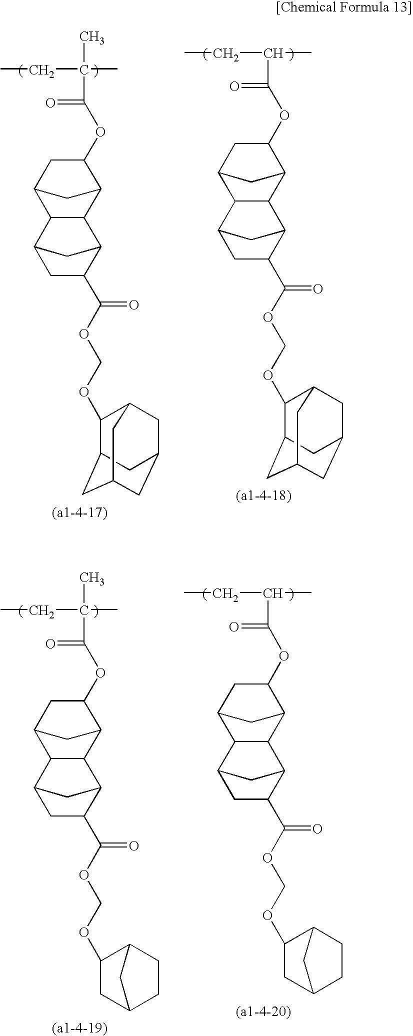

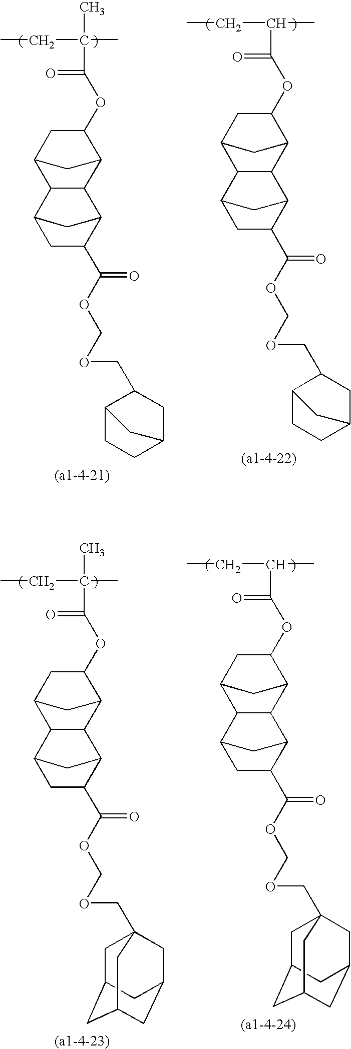

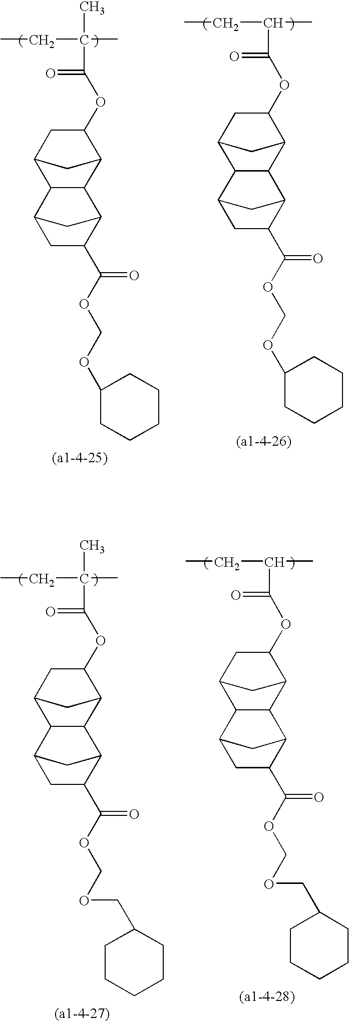

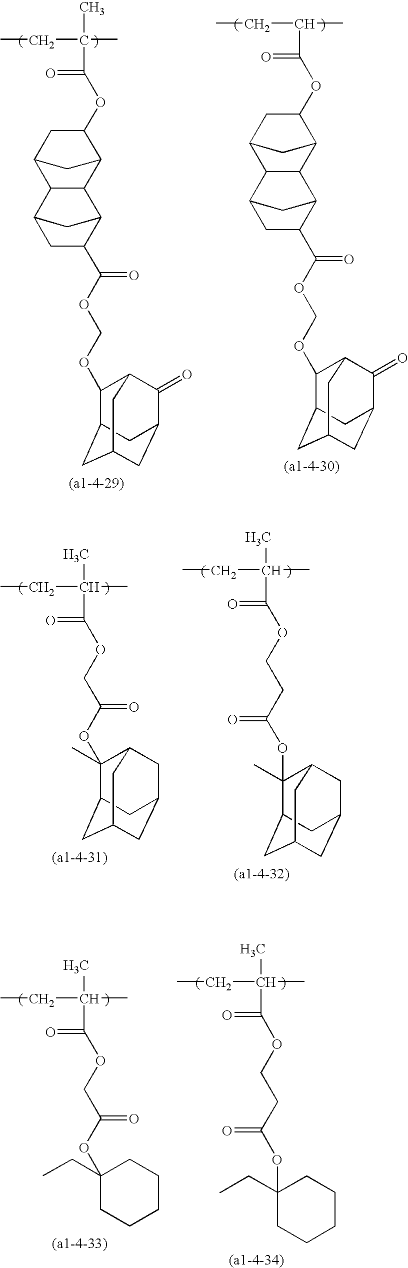

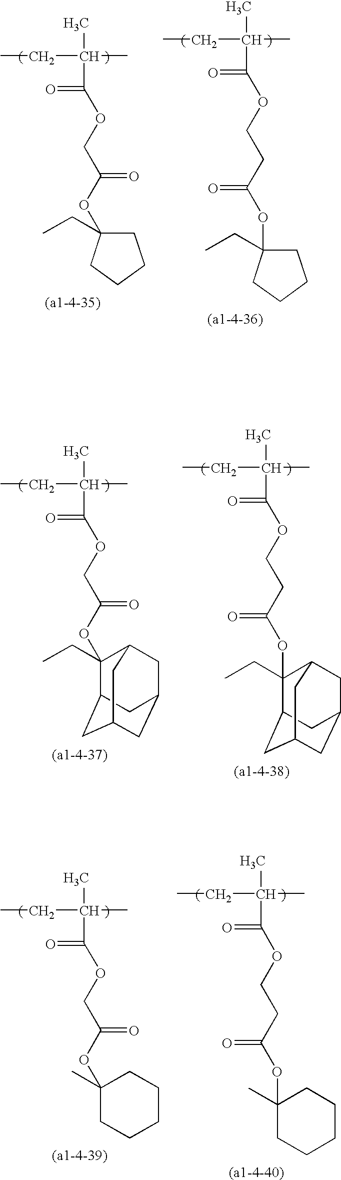

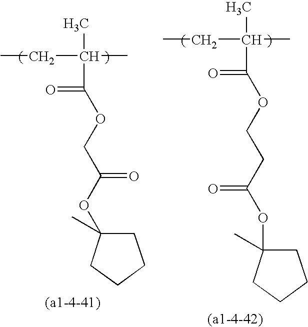

In terms of improving the effects of the present invention, a structural unit (a2-1) is more preferable as the structural unit (a2). Among the above-mentioned examples, at least one structural unit selected from the group consisting of structural units represented by formulas (a1-2-9), (a1-2-10), (a1-2-13), (a1-2-14), (a1-2-15) and (a1-2-16) is preferable, and at least one structural unit selected from the group consisting of structural units represented by formulas (a1-2-9) and (a1-2-10) is most preferable.

As the structural unit (a2), one type of structural unit may be used, or two or more types may be used in combination.

In the component (A), the amount of the structural unit (a2) based on the combined total of all structural units constituting the component (A) is preferably 5 to 50 mol %, more preferably 10 to 40 mol %, and still more preferably 15 to 35 mol %. By making the amount of the structural unit (a2) at least as large as the lower limit of the above-mentioned range, a pattern can be easily formed using a positive resist composition prepared from the component (A). On the other hand, by making the amount of the structural unit (a2) no more than the upper limit of the above-mentioned range, a good balance can be achieved with the other structural units.

[Other Structural Units]

The component (A) may include a structural unit (a4) derived from styrene, as well as the structural unit (a1) and the structural unit (a2).

In the present invention, the structural unit (a4) is not essential. However, including the structural unit (a4) is advantageous in that the solubility in an alkali developing solution can be adjusted, and dry etching resistance is improved.

In the present description and claims, the term “styrene” is a general concept which includes styrene and styrene in which the hydrogen atom on the α-position thereof has been substituted with a substituent such as an alkyl group.

The term “structural unit derived from styrene” refers to a structural unit which is formed by the cleavage of the ethylenic double bond of styrene. Styrene may have the hydrogen atoms of the phenyl group substituted with substituents such as alkyl groups of 1 to 5 carbon atoms.

As a preferable example of the structural unit (a4), a structural unit represented by general formula (a4-1) shown below can be exemplified.

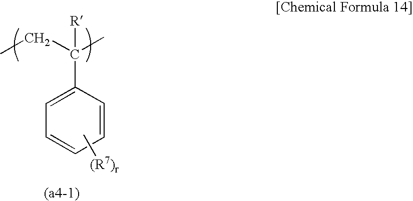

wherein R′ is as defined above; R⁷ represents a lower alkyl group of 1 to 5 carbon atoms; and r represents an integer of 0 to 3.

In general formula (a4-1) above, R′ and R⁷ are the same as R′ and R⁵ in general formula (a1-1).

r is an integer of 0 to 3, preferably 0 or 1, and most preferably 0 industrially.

When r is 1, the substitution position of R⁷ may be either the o-position, m-position or p-position of the phenyl group.

When r is 2 or 3, a desired combination of the substitution positions can be used. Further, when r is 2 or 3, the plurality of R⁷ may the same or different.

As the structural unit (a4), one type of structural unit may be used, or two or more types may be used in combination.

When the component (A) includes the structural unit (a4), the amount of the structural unit (a4) based on the combined total of all structural units constituting the component (A) is preferably 1 to 20 mol %, more preferably 3 to 15 mol %, and still more preferably 5 to 15 mol %. By making the amount of the structural unit (a4) at least as large as the lower limit of the above-mentioned range, the effect of including the structural unit (a4) can be enhanced. On the other hand, by making the amount of the structural unit (a4) no more than the upper limit of the above-mentioned range, a good balance can be achieved with the other structural units.

The component (A) may also include a structural writ (a5) which is other than the above-mentioned structural units (a1), (a2) and (a4), as long as the effects of the present invention are not impaired.

As the structural unit (a5), any other structural unit which cannot be classified as one of the above structural units (a1), (a2) and (a4) can be used without any particular limitations, and any of the multitude of conventional structural units used within resist resins for ArF excimer lasers or KrF excimer lasers (and particularly for ArF excimer lasers) can be used, such as a structural unit derived from acrylate ester containing a non-acid dissociable aliphatic polycyclic group, a structural unit derived from an acrylate ester containing a lactone-containing cyclic group, and a structural unit derived from an acrylate ester containing a polar group-containing aliphatic hydrocarbon group.

In the present invention, the component (A) is a resin component containing at least the structural unit (a1) and the structural unit (a2). As such a resin component, a copolymer including the structural unit (a1) and the structural unit (a2), and a copolymer including the structural unit (a1), the structural unit (a2) and the structural unit (a4) may be exemplified.

As the component (A), one type of resin may be used, or two or more types may be used in combination.

As the component (A), it is particularly desirable to use a resin comforting a copolymer represented by general formula (A-11) shown below which includes two structural units.

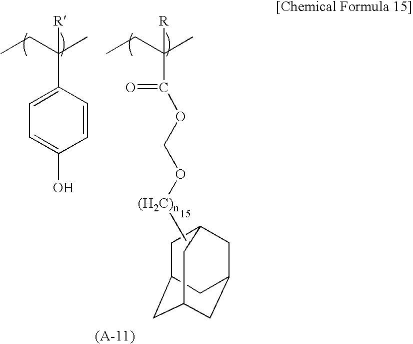

wherein R′ and R are as defined above; and n₁₅ is 0 or 1.

In formula (A-11), R′ is preferably a hydrogen atom or a methyl group, and a hydrogen atom is particularly desirable.

R is preferably a hydrogen atom or a methyl group, and a methyl group is particularly desirable.

It is particularly desirable that n₁₅ be 0.

The bonding position of adamantane and —CH₂—O—(CH₂)ₙ₁₅— is preferably the 1st or 2nd position of adamantane, and more preferably the 2nd position.

The component (A) can be obtained, for example, by a conventional radical polymerization or the like of the monomers corresponding with each of the structural units, using a radical polymerization initiator such as azobisisobutyronitrile (AIBN).

Furthermore, in the component (A), by using a chain transfer agent such as HS—CH₂—CH₂—CH₂—C(CF₃)₂—OH, a —C(CF₃)₂—OH group can be introduced at the terminals of the component (A). Such a copolymer having introduced a hydroxyalkyl group in which some of the hydrogen atoms of the alkyl group arc substituted with fluorine atoms is effective in reducing LWR (line width roughness: non-uniformity of the line width of a line pattern), and is also effective in reducing developing defects and LER (line edge roughness: unevenness of the side walls of a line pattern).

The weight average molecular weight (Mw) (the polystyrene equivalent value determined by gel permeation chromatography) of the component (A) is not particularly limited, but is preferably 2,000 to 50,000, more preferably 3,000 to 30,000, and most preferably 5,000 to 20,000. By making the weight average molecular weight no more than the upper limit of the above-mentioned range, the component (A) exhibits satisfactory solubility in a resist solvent when used as a resist. On the other hand, by making the weight average molecular weight at least as large as the lower limit of the above-mentioned range, dry etching resistance and cross-sectional shape of the resist pattern becomes satisfactory.

Further, the dispersity (Mw/Mn) is not particularly limited, and is preferably 1.0 to 5.0, more preferably 1.0 to 3.0, and most preferably 1.2 to 2.5. Here, Mn is the number average molecular weight.

In the positive resist composition of the present invention, the amount of the component (A) can be appropriately adjusted depending on the thickness of the resist film to be formed, and the like.

<Component (B)>

In the positive resist composition of the present invention, the component (B) contains an acid generator (B1) (hereafter, referred to as “component (B1)”) consisting of a compound represented by general formula (b1-1) shown below or an acid generator (B1′) (hereafter, referred to as “component (B1′)”) consisting of a compound represented by general formula (b1-1′) shown below.

By virtue of the component (B) containing the component (B1) or the component (B1′), the solubility of the positive resist composition in a typical resist solvent such as propylene glycol monomethyl ether acetate (PGMEA), propylene glycol monomethyl ether (PGME) or ethyl lactate (EL) becomes satisfactory. Further, by using the component (B1) in combination with the component (A) including the structural unit (a1) and the structural unit (a2), a resist pattern with high resolution or excellent shape can be formed.

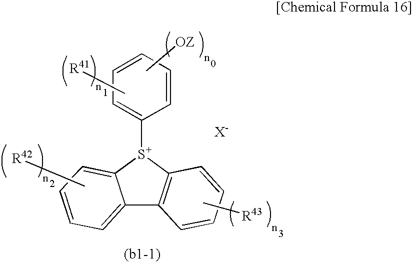

wherein Z represents a hydrogen atom or a group represented by general formula (b1-1-1) shown below; R⁴¹, R⁴² and R⁴³ each independently represents a halogen atom, a halogenated alkyl group, an alkyl group, an acetyl group, an alkoxy group, a carboxy group or a hydroxyalkyl group; no represents an integer of 1 to 3, and n₁ to n₃ each independently represents an integer of 0 to 3, with the proviso that n₀+n₁ is 5 or less; and X represents an anion;

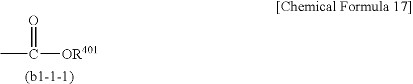

wherein R⁴⁰¹ represents an acid dissociable group.

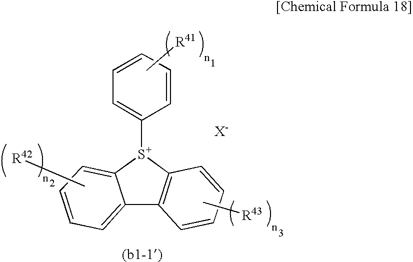

wherein R⁴¹, R⁴² and R⁴³ each independently represents a halogen atom, a halogenated alkyl group, an alkyl group, an acetyl group, an alkoxy group, a carboxy group or a hydroxyalkyl group; n₁, n₂ and n₃ each independently represents an integer of 0 to 3; and X⁻ represents an anion.

First, the component (B1) will he explained.

In general formula (b1-1), Z represents a hydrogen atom or a group, represented by general formula (b1-1-1) above.

In the present description, the acid generator (B1) in which Z in general formula (b1-1) represents hydrogen is referred to as “acid generator (B11)”. Further, the acid generator (B1) in which Z in general formula (b1-1) represents a group represented by general formula (b1-1-1) is referred to as “acid generator (B12)”.

Next, the acid generator (B11) and the acid generator (B12) will be explained.

[Acid Generator (B11)]

The acid generator (B11) is a compound represented by general formula (b1-1) in which Z is hydrogen.

By using the acid generator (B11) in combination with the component (A) including the structural unit (a1) and the structural unit (a1), a resist pattern with high resolution can be formed.

In general formula (b1-1) above, R⁴¹, R⁴² and R⁴³ each independently represents a halogen atom, a halogenated alkyl group, an alkyl group, an acetyl group, an alkoxy group, a carboxy group or a hydroxyalkyl group.

The alkyl group for R⁴¹, R⁴² and R⁴³ is preferably a lower alkyl group of 1 to 5 carbon atoms, and more preferably a linear or branched alkyl group. The alkyl group for R⁴¹, R⁴² and R⁴³ is more preferably a methyl group, ethyl group, propyl group, isopropyl group, n-butyl group, tert-butyl group, tert-pentyl group or isopentyl group, and a methyl group is particularly desirable.

The alkoxy group is preferably an alkoxy group of 1 to 5 carbon atoms, more preferably a linear or branched alkoxy group, and most preferably a methoxy group or ethoxy group.

The hydroxyalkyl group is preferably the aforementioned alkyl group in which one or more hydrogen atoms have been substituted with hydroxy groups, and examples thereof include a hydroxymethyl group, hydroxyethyl group and hydroxypropyl group.

Examples of halogen atoms include a fluorine atom, a chlorine atom, a bromine atom and an iodine atom, and a fluorine atom is preferable.

The halogenated alkyl group is preferably a halogenated alkyl group of 1 to 5 carbon atoms, more preferably a fluorinated alkyl group of 1 to 5 carbon atoms, still more preferably a trifluoromethyl group or a pentafluoroethyl group.

In general formula (b1-1) above, n₀ is an integer of 1 to 3, preferably 1 or 2, and more preferably 1.

n₁ is an integer of 0 to 3, preferably 1 or 2, and more preferably 2,

n₂ and n₃ each independently represents an integer of 0 to 3, preferably 0 or 1,and more preferably 0.

However, n₀+n₁ is 5 or less.

When the subscripts n₁ to n₃ of R⁴¹ to R⁴³ represent an integer of 2 or more, the plurality of R⁴¹ to R⁴³ may be the same or different.

In general formula (b1-1) above, X⁻ represents an anion.

As the anion moiety of X′, there is no particular limitation, and any anion moiety can be appropriately used which is known as an anion moiety of an onium salt-based acid generator. For example, an anion represented by general formula: R¹⁴SO₃⁻ (wherein R¹⁴ represents a linear, branched or cyclic alkyl group or a halogenated alkyl group) or an anion represented by general formula: R¹′—O—Y¹′—SO₃^{—} (wherein R¹′ represents a monovalent aliphatic hydrocarbon group, a monovalent aromatic organic group or a monovalent hydroxyalkyl group; and Y¹′ represents an alkylene group of 1 to 4 carbon atoms which may be fluorinated) can be used.

In general formula: R¹⁴SO₃′ above, R¹⁴ represents a linear, branched or cyclic alkyl group, a halogenated alkyl group, an aryl group or an alkenyl group.

The linear or branched alkyl group for R¹⁴ preferably has 1 to 10 carbon atoms, more preferably 1 to 8 carbon atoms, and most preferably 1 to 4 carbon atoms.

The cyclic alkyl group for R¹⁴ preferably has 4 to 15 carbon atoms, more preferably 4 to 10 carbon atoms, and most preferably 6 to 10 carbon atoms.

Among these, as R¹⁴, a halogenated alkyl group is preferable. That is, it is preferable that X⁻ in general formula (b1-1) is a halogenated alkylsulfonate ion. A “halogenated alkyl” is an alkyl group in which a portion or all of hydrogen atoms are substituted with halogen atoms. As the halogenated alkyl, the alkyl groups for R⁴¹, R⁴² and R⁴³ which have been substituted with halogen atoms may be exemplified. Examples of the halogen atoms with which hydrogen atoms are substituted include fluorine atoms, chlorine atoms, bromine atoms and iodine atoms. In the halogenated alkyl group, it is preferable that 50 to 100% of the hydrogen atoms are substituted with halogen atoms, and it is more preferable that all hydrogen atoms are substituted with halogen atoms.

As the halogenated alkyl group, a fluorinated alkyl group is preferable. The fluorinated alkyl group preferably has 1 to 10 carbon atoms, more preferably 1 to 8 carbon atoms, and most preferably 1 to 4 carbon atoms. The fluorination ratio of the fluorinated alkyl group (percentage of the number of fluorine atoms substituting the hydrogen atoms within the alkyl group, based on the total number of hydrogen atoms within the alkyl group prior to fluorination, and the same applies to the fluorination ratio described below) is preferably from 10 to 100%, more preferably from 50 to 100%, and it is particularly desirable that all of the hydrogen atoms are substituted with fluorine atoms, as the acid strength increases.

The aryl group for R¹⁴ is preferably an aryl group of 6 to 20 carbon atoms which may have a substituent. Examples of substituents include a halogen atom, a hetero atom and an alkyl group. The aryl group may have a plurality of substituents.

The alkenyl group for R¹⁴ is preferably an alkenyl group of 2 to 10 carbon atoms which may have a substituent. Examples of substituents include a halogen atom, a hetero atom and an alkyl group. The alkenyl group may have a plurality of substituents.

In general formula R¹′—O—Y¹′—SO₃⁻ above, R¹′ represents a monovalent aliphatic hydrocarbon group, a monovalent aromatic organic group or a monovalent hydroxyalkyl group; and Y¹′ represents an alkylene group of 1 to 4 carbon atoms which may be fluorinated.

As the monovalent aliphatic hydrocarbon group for R¹′, for example, a linear, branched or cyclic, monovalent saturated hydrocarbon group of 1 to 15 carbon atoms, or a linear or branched, monovalent unsaturated hydrocarbon group of 2 to 5 carbon atoms can be mentioned.

Examples of linear, monovalent saturated hydrocarbon groups include a methyl group, ethyl group, propyl group, butyl group; pentyl group, hexyl group, heptyl group, octyl group, nonyl group and decanyl group.

Examples of branched, monovalent saturated hydrocarbon groups include a 1-methylethyl group, 1-methylpropyl group, 2-methylpropyl group, 1-methylbutyl group, 2-methylbutyl group, 3-methylbutyl group, 1-ethylbutyl group, 2-ethylbutyl group, 1-methylpentyl group, 2-methylpentyl group, 3-methylpentyl group and 4-methylpentyl group.

The cyclic, monovalent saturated hydrocarbon group may be either a polycyclic group or a monocyclic group. For example, groups in which one hydrogen atom has been removed from a monocycloalkane or a polycycloalkane such as a bicycloalkane, tricycloalkane or tetracycloalkane can be mentioned. Specific examples include groups in which one hydrogen atom has been removed from a monocycloalkane such as cyclopentane, cyclohexane, cycloheptane or cyclooctane; and groups in which one hydrogen atom has been removed from a polycycloalkane such as adamantane, norbornane, isobornane, tricyclodecane or tetracyclododecane.

Examples of linear, monovalent unsaturated hydrocarbon group include a propenyl group (allyl group) and butynyl group.

Examples of branched, monovalent unsaturated hydrocarbon group include 1-methylpropenyl group and 2-methylpropenyl group.

The monovalent aliphatic hydrocarbon group for R¹′ preferably has 3 to 4 carbon atoms, and it is particularly desirable that the monovalent aliphatic hydrocarbon group have 3 carbon atoms.

Examples of monovalent aromatic organic groups for R¹′ include aryl groups in which one hydrogen atom has been removed from an aromatic hydrocarbon ring, such as a phenyl group, a biphenyl group, a fluorenyl group, a naphthyl group, an anthryl group, and a phenantryl group; and heteroaryl groups in which some of the carbon atoms constituting the ring(s) of these groups are substituted with hetero atoms such as an oxygen atom, a sulfur atom, and a nitrogen atom. These aryl groups and heteroaryl groups may have a substituent such as an alkyl group of 1 to 10 carbon atoms, a halogenated alkyl group, an alkoxy group, a hydroxyl group or a halogen atom. The alkyl group or halogenated alkyl group as the substituent preferably has 1 to 8 carbon atoms, and more preferably 1 to 4 carbon atoms. The halogenated alkyl group is preferably a fluorinated alkyl group. Examples of halogen atoms include a fluorine atom, a chlorine atom, a bromine atom and an iodine atom, and a fluorine atom is preferable.

The monovalent hydroxyalkyl group for R¹′ is a linear, branched or cyclic, monovalent saturated hydrocarbon group in which at least one hydrogen atom has been substituted with a hydroxyl group. Among these, linear or branched, monovalent saturated hydrocarbon groups which one or two hydrogen atoms have been substituted with hydroxyl groups are preferable. Specific examples include a 1-hydroxypropyl group, 2-hydroxypropyl group, 3-hydroxypropyl group and 2,3-dihydroxypropyl group.

The monovalent hydroxyalkyl group for R¹′ preferably has 3 to 10 carbon atoms, more preferably 3 to 8 carbon atoms, and most preferably 3 to 6 carbon atoms.

Examples of alkylene groups of 1 to 4 carbon atoms for Y¹′ which may be fluorinated include —CF₂—, —CF₂CF₂—, —CF₂CF₂CF₂—, —CF(CF₃)CF₂—, —CF(CF₂CF₃)—, —C(CF₃)₂—, —CF₂CF₂CF₂CF₂—, —CF(CF₃)CF₂CF₂—, —CF₂CF(CF₃)CF₂-, —CF(CF₃)CF(CF₃)—, —C(CF₃)₂CF₂—, —CF(CF₂CF₃)CF₂—, —CF(CF₂CF₂CF₃)—, —C(CF₃)(CF₂CF₃)—; —CHF—, —CH₂CF₂—, —CH₂CH₂CF₂—, —CH₂CF₂CF₂—, —CH(CF₃)CH₂—, —CH(CF₂CF₃—, —C(CH₃)(CF₃)—, —CH₂CH₂CH₂CF₂—, —CH₂CH₂CF₂CF₂—, —CH(CF₃)CH₂CH₂—, —CH₂CH(CF₃)CH₂—, —CH(CF₃)CH(CF₃)—, —C(CF₃)₂CH₂—; —CH₂—, —CH₂CH₂—, —CH₂CH₂CH₂—, —CH(CH₃)CH₂—, —CH(CH₂CH₃)—, —C(CH₃)₂—, —CH₂CH₂CH₂CH₂—, —CH(CH₃)CH₂CH₂—, —CH₂CH(CH₃)CH₂—, —CH(CH₃)CH(CH₃)—, —C(CH₃)₂CH₂—, —CH(CH₂CH₃)CH₂—, —CH(CH₂CH₂CH₃)—, and —C(CH₃)(CH₂CH₃)—.

As the alkylene group of 1 to 4 carbon atoms for Y¹′ which may be fluorinated, it is preferable that the carbon atom bonded to S be fluorinated. Examples of such fluorinated alkylene groups include —CF₂—, —CF₂CF₂—, —CF₂CF₂CF₂—, —CF(CF₃)CF₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—; —CH₂CF₂—, —CH₂CH₂CF₂—, —CH₂CF₂CF₂—; —CH₂CH₂CH₂CF₂—, —CH₂CH₂CF₂CF₂—, and —CH₂CF₂CF₂CF₂—.

Among these, —CF₂CF₂—, —CF₂CF₂CF₂—, and CH₂CF₂CF₂— are preferable, —CF₂CF₂— and —CF₂CF₂CF₂— are more preferable, and —CF₂CF₂— is particularly desirable.

In general formula (b1-1) above, as anions other than those exemplified above for X″, anions represented by general formula (b-3) shown below and anions represented by general formula (b-4) shown below may be used.

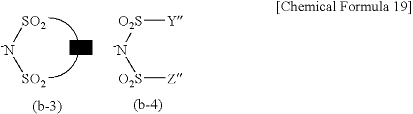

wherein X⁻ represents an alkylene group of 2 to 6 carbon atoms in which at least one hydrogen atom has been substituted with a fluorine atom; and Y″ and Z″ each independently represents an alkyl group of 1 to 10 carbon atoms in which at least one hydrogen atom has been substituted with a fluorine atom.

In general formula (b-3) above, X⁻ represents a linear or branched alkylene group in which at least one hydrogen atom has been substituted with a fluorine atom, and the alkylene group preferably has 2 to 6 carbon atoms, more preferably 3 to 5 carbon atoms, and most preferably 3 carbon atoms.

In general formula (b-4) above, Y″ and Z″ each independently represents a linear or branched alkyl group in which at least one hydrogen atom has been substituted with a fluorine atom, and the alkyl group preferably has 1 to 10 carbon atoms, more preferably 1 to 7 carbon atoms, and most preferably 1 to 3 carbon atoms.

The smaller the number of carbon atoms of the alkylene group for X⁻ or those of the alkyl group for Y″ and Z″ within the above-mentioned range of the number of carbon atoms, the more the solubility in a resist solvent is improved.

Further, in the alkylene group for X⁻ or the alkyl group for Y″ and Z″, it is preferable that the number of hydrogen atoms substituted with fluorine atoms is as large as possible because the acid strength increases and the transparency to high energy radiation of 200 nm or less or electron beam is improved. The fluorination ratio the alkylene group or alkyl group is preferably from 70 to 100%, more preferably from 90 to 100%, and it is particularly desirable that the alkylene group or alkyl group be a perfluoroalkylene or perfluoroalkyl group in which all hydrogen atoms are substituted with fluorine atoms.

Specific examples of compounds preferable as the acid generator (B11) are shown below.

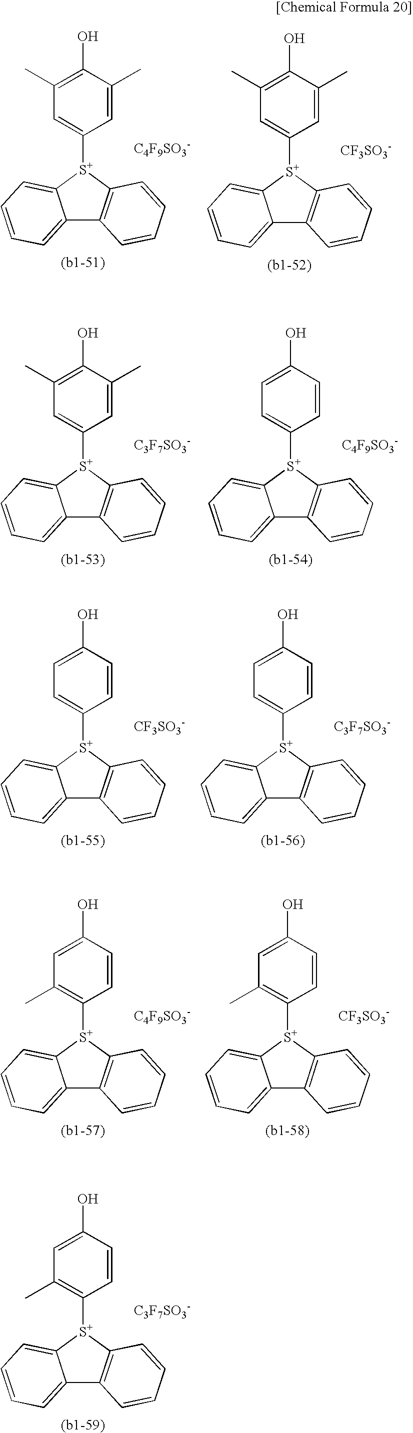

Among these, as the acid generator (B11), the compound represented by chemical formula (b1-51) above is particularly desirable.

(Production Method of Acid Generator (B11))

The acid generator (B11) can be produced, for example, as follows. A compound represented by general formula (b1-5-20) shown below is added to a methanesulfonic acid solution of diphosphorus pentaoxide, and the resultant is cooled to about room temperature. Then, a compound represented by general formula (b1-5-21) is gradually added thereto, and a reaction is effected at room temperature for 2 to 40 hours, preferably 5 to 20 hours. Thereafter, the reaction product is washed with a mixed solvent of water and an organic solvent (e.g., dichloromethane, chlorobenzene, iodobezene, or the like), and the water phase is extracted. Then, for example, a potassium salt represented by general formula (b1-5-22) shown below is added thereto, and a reaction is effected at room temperature for 0.5 to 8 hours, preferably 1.0 to 4 hours, thereby obtaining the acid generator (B11).

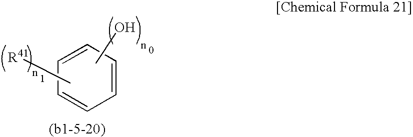

wherein R⁴¹, n₀ and n₁ are the same as R⁴¹, n₀ and n₁ defined in general formula (b1-1) above, respectively.

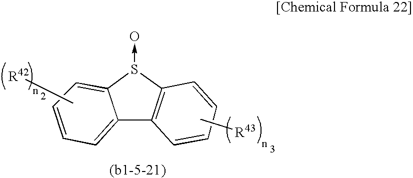

wherein R⁴², R⁴³, n₂ and n₃ are the same as R⁴², R⁴³, n₂ and n₃ defined in general formula (b1-1) above, respectively.

K⁺X⁻ (b1-5-22)

wherein X⁻ is the same as X⁻ defined in general formula (b1-1) above

As the acid generator (B11), one type may be used, or two or more types may be used in combination.

In the positive resist composition of the present invention, the amount of the acid generator (B11) relative to 100 parts by weight of the component (A) is preferably 0.5 to 45 parts by weight, more preferably 1 to 40 parts by weight, still more preferably 5to 30 parts by weight, most preferably 10 to 25 parts by weight. By making the amount of the acid generator (B11) at least as large as the lower limit of the above-mentioned range, a resist pattern with high resolution can be formed. On the other hand, by making the amount of the acid generator (B11) no more than the upper limit of the above-mentioned range, storage stability becomes satisfactory.

[Acid Generator (B12)]

The acid generator (B12) is a compound in which Z in general formula (b1-1) above is a group represented by general formula (b1-1-1) above.

By using the acid generator (B12) in combination with the component (A) including the structural unit (a1) and the structural unit (a2), a resist pattern having an excellent shape can be formed.

In general formula (b1-1-1), R⁴⁰¹ represents an acid dissociable group.

As the acid dissociable group for R⁴⁰¹, there is no particular limitation as long as it is an organic group which can be dissociated by action of acid. Examples of acid dissociable groups include cyclic or linear tertiary alkyl ester-type acid dissociable groups and acetal-type acid dissociable groups such as alkoxyalkyl groups. Among these, tertiary alkyl ester-type acid dissociable groups are preferable.

R⁴⁰¹ is preferably an acid dissociable group represented by general formula (b1-1-10) shown below.

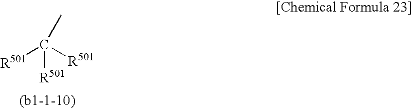

wherein the plurality of R⁵⁰¹ may be the same or different, and at least one R⁵⁰¹ represents a linear or branched alkyl group of 1 to 4 carbon atoms; and the remaining two R⁵⁰¹ each independently represents a linear or branched alkyl group of 1 to 4 carbon atoms or a monovalent aliphatic cyclic group of 4 to 20 carbon atoms, or the remaining two R⁵⁰¹ may be bonded to each other to form a divalent aliphatic cyclic group of 4 to 20 carbon atoms including the carbon atom to which the two R⁵⁰¹ are bonded.

In general formula (b1-1-10), examples of the linear or branched alkyl group of 1 to 4 carbon atoms for R⁵⁰¹ include a methyl group, ethyl group, propyl group, isopropyl group, n-butyl group, isobutyl group and tert-butyl group.

As aliphatic cyclic groups, groups in which one or more hydrogen atoms have been removed from a monocycloalkane or a polycycloalkane such as a bicycloalkane, tricycloalkane or tetracycloalkane may be exemplified. Specific examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, tricyclodecane or tetracyclododecane. More specific examples include a cyclopentyl group, a cyclohexyl group, a norbornyl group and an adamantyl group.

As the acid dissociable group represented by general formula (b1-1-10) above, examples of those in which the plurality of R⁵⁰¹ each independently represents a linear or branched alkyl group of 1 to 4 carbon atoms include a tert-butyl group, a tert-pentyl group and a tert-hexyl group.

As the acid dissociable group represented by general formula (b1-1-10) above, examples of those in which at least one R³⁰¹ represents a linear or branched alkyl group of 1 to 4 carbon atoms and the remaining two R⁵⁰¹ each independently represents a linear or branched alkyl group of 1 to 4 carbon atoms or a monovalent aliphatic cyclic group of 4 to 20 carbon atoms include a 1-(1-adamantyl)-1-methylethyl group, a 1-(1-adamantyl)-methylpropyl group, a 1-(1-adamantyl)-methylbutyl group, a 1-(1-adamantyl)-methylpentyl group, a 1-(1-cyclopentyl)-1-methylethyl group, a 1-(1-cyclopentyl)-1-methypropyl group, a 1-(1-cyclopentyl)-1-methybutyl group, a 1-(1-cyclopentyl)-1-methypentyl group, a 1-(1-cyclohexyl)-1-methyethyl group, a 1-(1-cyclohexyl)-1-methypropyl group, a 1-(1-cyclohexyl)-1-methybutyl group and a 1-(1-cyclohexyl)-1-methypentyl group.

As the acid dissociable group represented by general formula (b1-1-10) above, examples of those in which one R⁵⁰¹ represents a linear or branched alkyl group of 1 to 4 carbon atoms and the remaining two R⁵⁰¹ are bonded to each other to form a divalent aliphatic cyclic group of 4 to 20 carbon atoms including the carbon atom to which the two R⁵⁰¹ are bonded include a 2-methyl-2-adamantyl group, a 2-ethyl-2-adamantyl group, a 1-methyl-1-cyclopentyl group, a 1-ethyl-1-cyclopentyl group, a 1-methyl- 1-cyclohexyl group and a 1-ethyl-1-cyclohexyl group.

Among these, those in which the plurality of R⁵⁰¹ each independently represents a linear or branched alkyl group of 1 to 4 carbon atoms are preferable, and those in which the plurality of R⁵⁰¹ each independently represents a tert-butyl group is particularly desirable.

With respect to the acid generator (B12), R⁴¹, R⁴², R⁴³, n₀, n₁, n₂, n₃ and X³¹ in general formula (b1-1) above are the same as R⁴¹, R⁴², R⁴³, n₀, n₁, n₂, n₃ and X⁻ in general formula in the acid generator (B11).

As the acid generator (B12), specific examples of those in which the plurality of R⁵⁰¹ in general formula (b1-1-10) each independently represents a linear or branched alkyl group of 1 to 4 carbon atoms include compounds represented by formulas (b1-81) to (b1-89) shown below.

Further, specific examples of those in which at least one R⁵⁰¹ represents a linear or branched alkyl group of 1 to 4 carbon atoms and the remaining two R⁵⁰¹ each independently represents a linear or branched alkyl group of 1 to 4 carbon atoms or a monovalent aliphatic cyclic group of 4 to 20 carbon atoms include compounds represented by formulas (b1-91) to (b1-99) shown below.

Furthermore, specific examples of those in which at least one R⁵⁰¹ represents a linear or branched alkyl group of 1 to 4 carbon atoms and the remaining two R⁵⁰¹ are bonded to each other to form a divalent aliphatic cyclic group of 4 to 20 carbon atoms including the carbon atom to which the two R⁵⁰¹ are bonded include compounds represented by formulas (b1-101) to (b1-119) shown below.

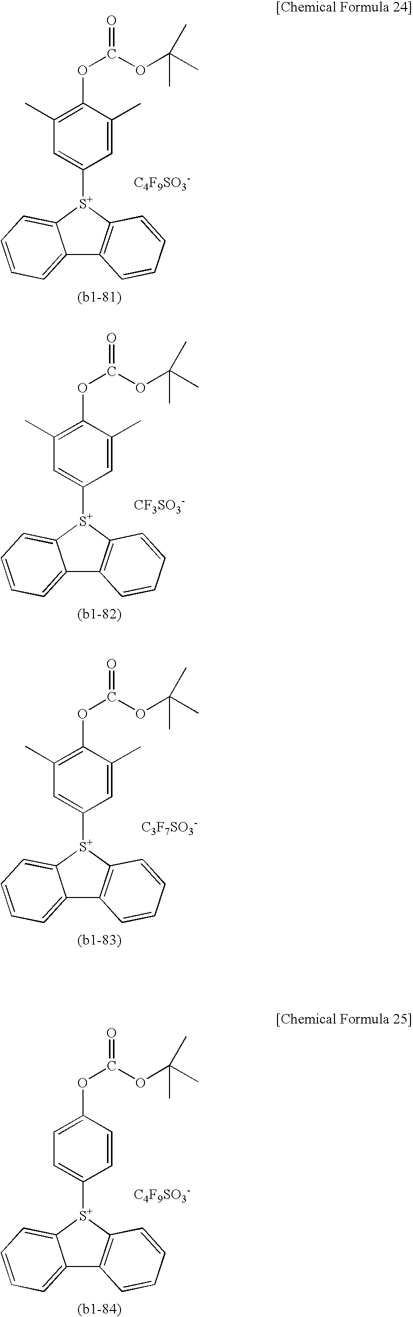

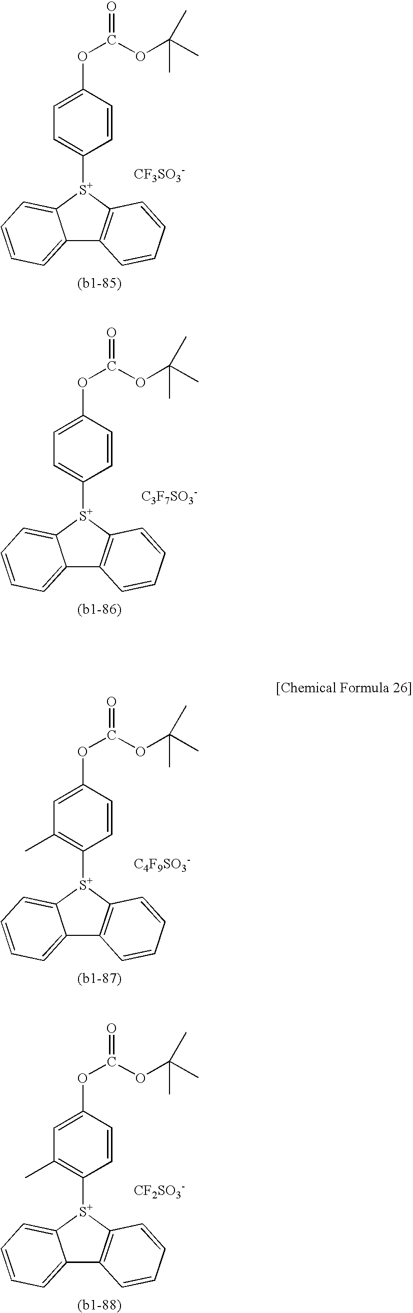

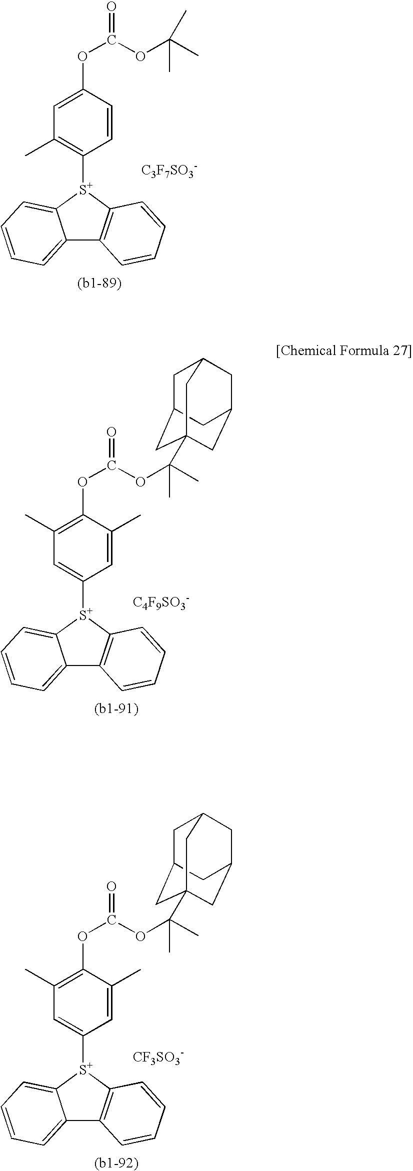

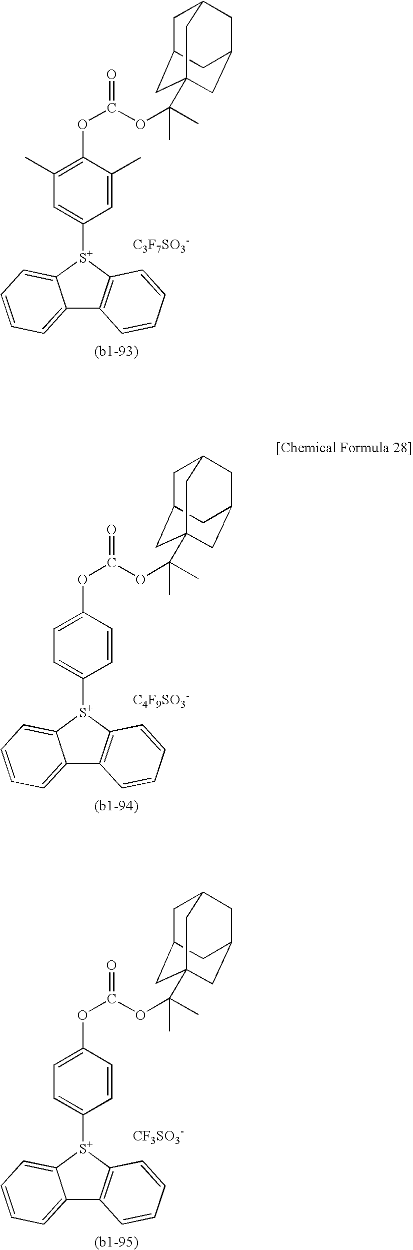

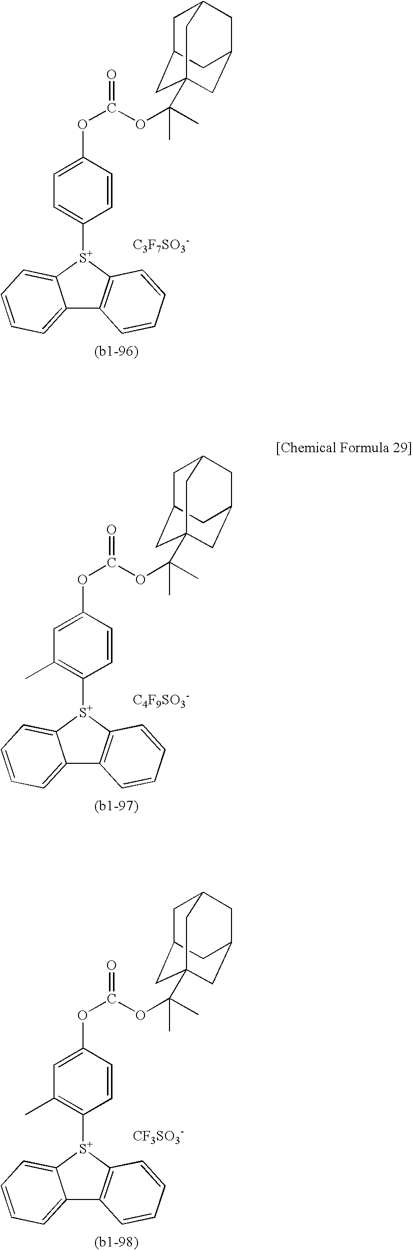

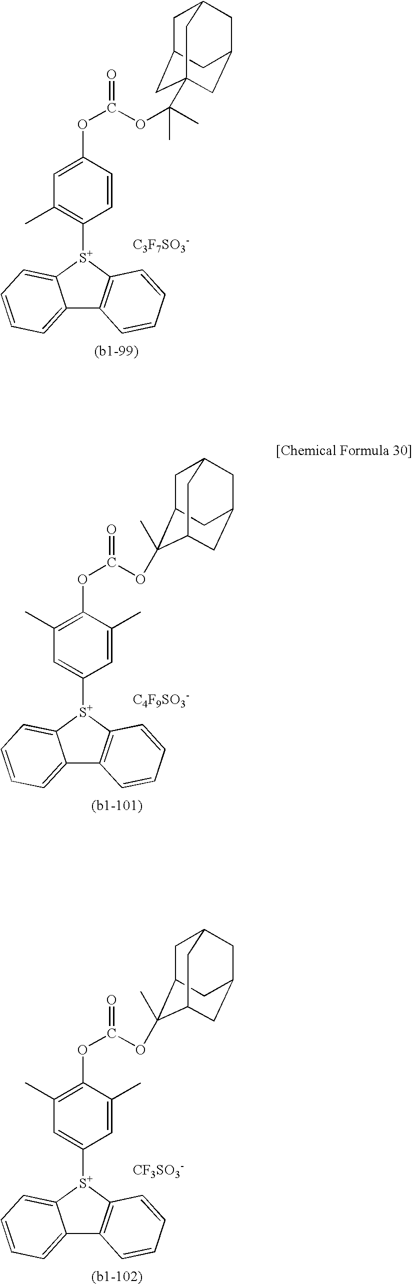

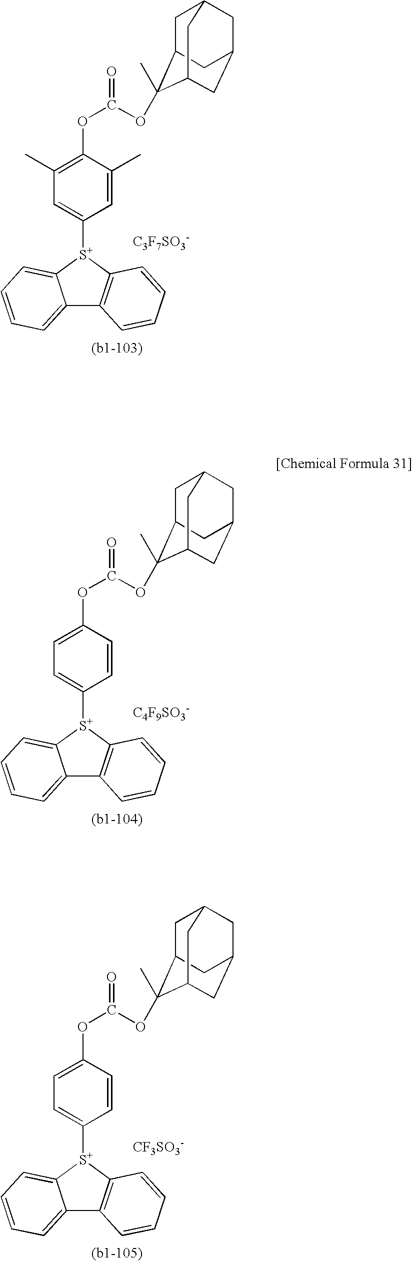

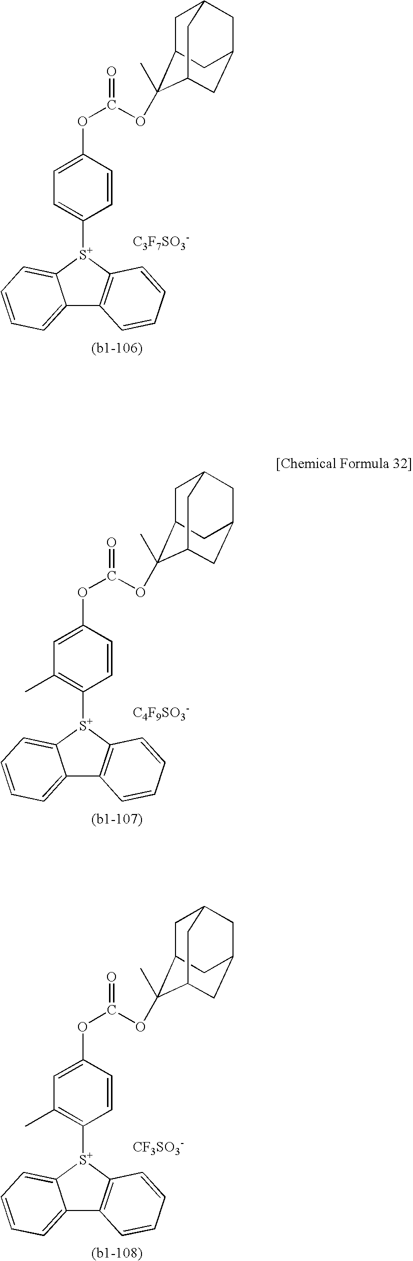

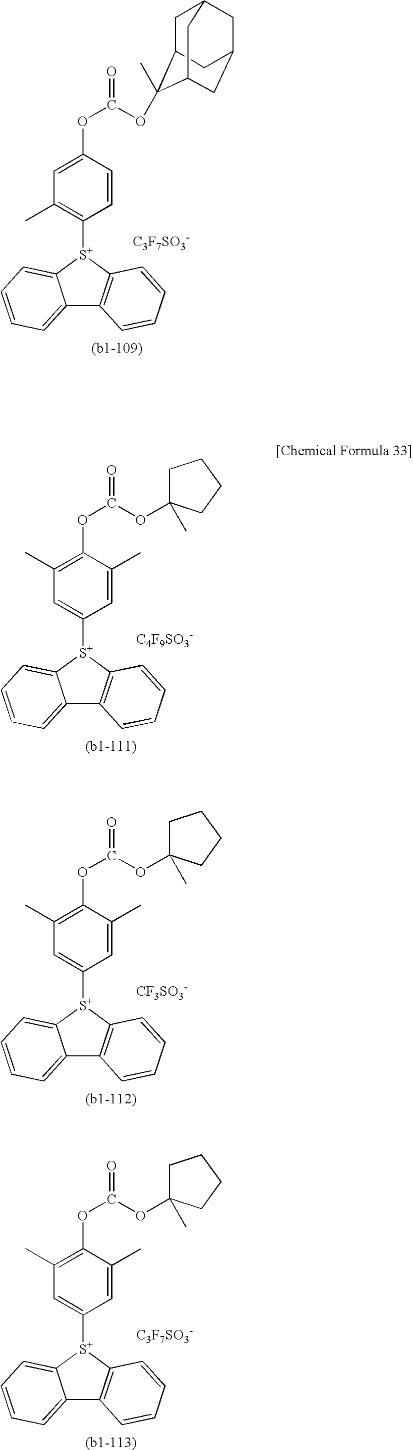

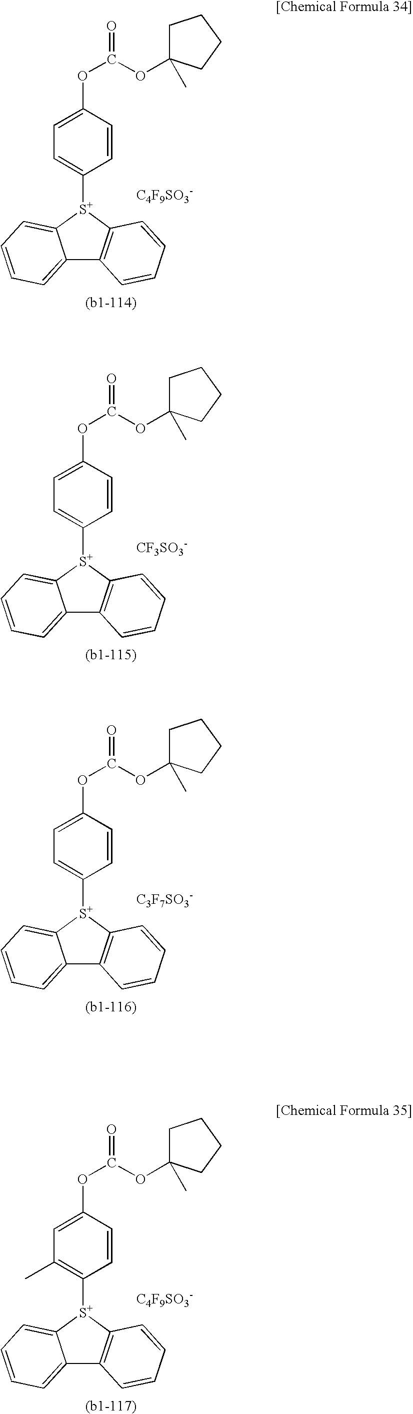

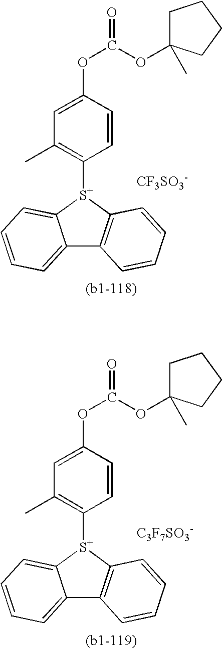

Among these, as the acid generator (B12), the compound represented by chemical formula (b1-81) is particularly desirable.

(Production Method of Acid Generator (B12))

The acid generator (B12) can be produced, for example, as follows. A compound represented by general formula (b1-1) in which Z is hydrogen (i.e., the acid generator (B11)), a compound represented by general formula (b1-8-20) shown below, and an amine catalyst (e.g., N,N-dimethylaminopyridine, triethylamine, or the like) are added to an organic solvent (e.g., dichloromethane, tetrahydrofuran, or the like), and a reaction is effected at 5 to 50° C. for 10 minutes to 12 hours, preferably 30 minutes to 3 hours. Then, the reaction product is washed with diluted hydrochloric acid, water or the like, and, for example, an organic solvent (e.g., dichloromethane, tetrahydrofuran, or the like) solution of the reaction product can be dropwise added to a poor solvent (e.g., hexane, dibutylether, or the like), thereby obtaining the acid generator (B12).

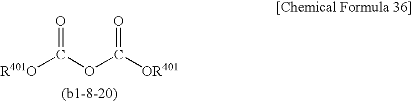

wherein R^{40l} is the same as R⁴⁰¹ defined for general formula (b1-1-1) above.

As the acid generator (B12), one type may be used, or two or more types may be used in combination.

In the positive resist composition of the present invention, the amount of the acid generator (B12) relative to 100 parts by weight of the component (A) is preferably 0.5 to 45 parts by weight, more preferably 1 to 40 parts by weight, still more preferably 5to 30 parts by weight, most preferably 10 to 25 parts by weight. By making the amount of the acid generator (B12) at least as large as the lower limit of the above-mentioned range, the effect of inhibiting dissolution of the unexposed portions of the resist film in an alkali developing solution is enhanced, and hence, a resist pattern having an excellent shape can be formed. On the other hand, by making the amount of the acid generator (B12) no more than the upper limit of the above-mentioned range, storage stability becomes satisfactory.

As the component (B1), one type may be used, or two or more types may be used in combination. As the component (B1), the acid generator (B11) and the acid generator (B12) may be used in combination.

Next, the component (B1′) will be explained.

In general formula (b1-1′) above, R⁴¹, R⁴² and R⁴³ each independently

represents a halogen atom, a halogenated alkyl group, an alkyl group, an acetyl group, an alkoxy group, a carboxy group or a hydroxyalkyl group, and the same as R⁴¹, R⁴² and R⁴³in general formula (b1-1) may be exemplified.

n₁ is an integer of 0 to 3, preferably 0 to 2, more preferably 0 or 1, and still more preferably 0.

n₂ and n₃ are the same as n₂ and n₃ in general formula (b1-1) above.

X⁻ represents an anion, and the same as X⁻ in general formula (b1-1) may be exemplified.

Specific examples of the component (B1′) are shown below.

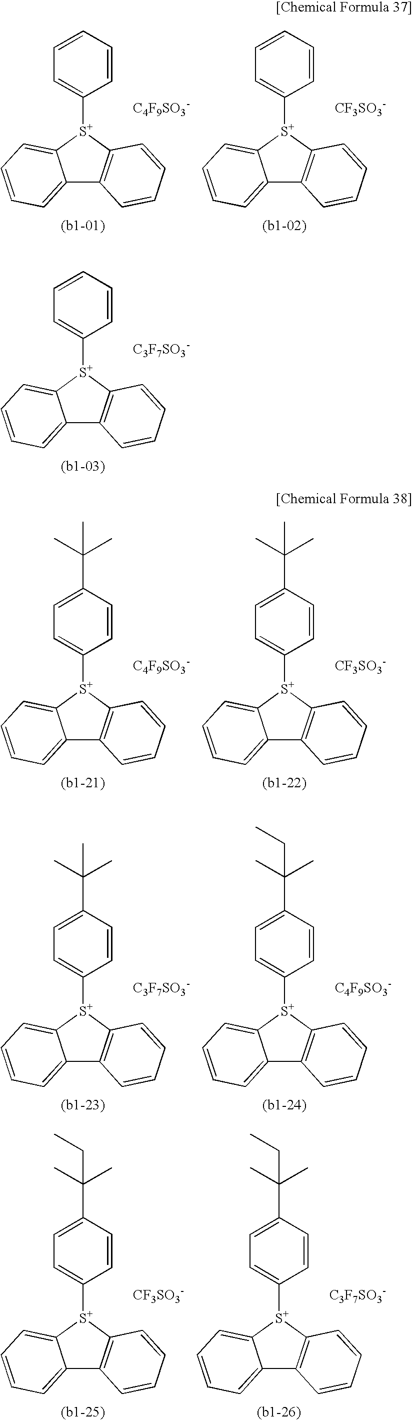

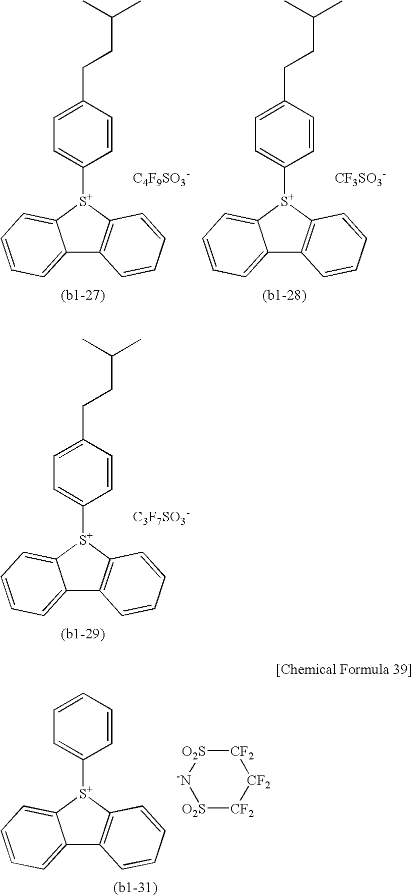

Among these, as the component (B1′), the compound represented by chemical formula (b1-01) or the compound represented by chemical formula (b1-31) is particularly desirable.

(Production Method of Acid Generator (B1′))

The component (B1′) can be produced, for example, by reacting a compound represented by general formula (b1-0-21) shown below with a compound represented by general formula (b1-0-22) in a solvent such as chlorobenzene, or iodobenzene in the presence of a catalyst such as copper (II) benzoate at 80 to 130° C., preferably 100 to 120° C., for 0.5 to 30 hours, preferably 1 to 2 hours.

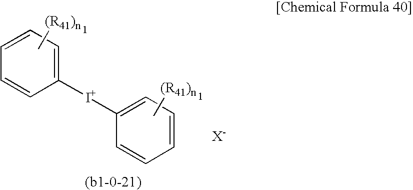

wherein R⁴¹, n₁ and X⁻ are the same as R⁴¹, n₁ and X⁻ in general formula (b1-1′) above.

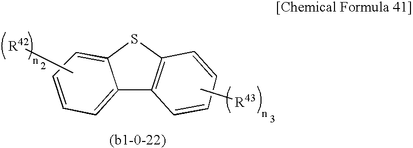

wherein R⁴², R⁴³, n₂ and n₃ are the same as R⁴², R⁴³, n₂ and n₃ in general formula (b1-1′) above.

As the component (B1′), one type may be used, or two or more types may be used in combination.

In the positive resist composition of the present invention, the amount of the component (B1) or the component (B1′) based on the entire component (B) is not particularly limited, but is preferably 5 to 100% by weight, more preferably 40 to 100% by weight, still more preferably 70 to 100% by weight, and most preferably 100% by weight. By making the amount of the component (B1) or the component (B1′) at least as large as the lower limit of the above-mentioned range, a resist pattern with high resolution or excellent shape can be formed.

In the positive resist composition of the present invention, the amount of the component (B1) or the component (B1′) relative to 100 parts by weight of the component (A) is preferably within the range of 0.5 to 45 parts by weight, more preferably 1 to 40 parts by weight, still more preferably 5 to 30 parts by weight, and most preferably 10 to 25 parts by weight. By making the amount of the component (B1) or the component (B1′) at least as large as the lower limit of the above-mentioned range, a resist pattern with high resolution or excellent shape can be formed. On the other hand, by making the amount of the component (B1) or the component (B1′) no more than the upper limit of the above-mentioned range, storage stability becomes satisfactory.

In the component (B), an acid generator (B2) other than the aforementioned component (B1) and component (B1′) (hereafter, referred to as “component (B2)”) may be used in combination with the component (B1) or the component (B1′).

As the component (B2), there is no particular limitation as long as it is an acid generator other than the component (B1) and (B1′), and any of the known acid generators used in conventional chemically amplified resist compositions can be used.

Examples of these acid generators are numerous, and include onium salt-based acid generators such as iodonium salts and sulfonium salts; oxime sulfonate-based acid generators; diazomethane-based acid generators such as bisalkyl or bisaryl sulfonyl diazomethanes and poly(bis-sulfonyl)diazomethanes; nitrobenzylsulfonate-based acid generators; iminosulfonate-based acid generators; and disulfone-based acid generators.

As an onium salt-based acid generator, a compound represented by general formula (b-1) or (b-2) shown below can be used.

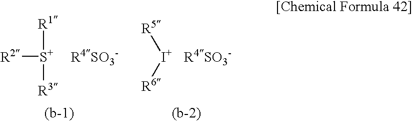

wherein R¹″ to R³″, R⁵″ and R⁶″ each independently represents an aryl group or alkyl group, wherein two of R¹″ to R³″ in formula (b-1) may be bonded to each other to form a ring with the sulfur atom; and R⁴″ represents a linear, branched or cyclic alkyl group or fluorinated alkyl group, with the proviso that at least one of R¹″ to R³″ represents an aryl group, and at least one of R⁵″ and R⁶″ represents an aryl group.

In formula (b-1), R¹″ to R³″ each independently represents an aryl group or an alkyl group. In formula (b-1), two of R¹″ to R³″ in formula (b-1) may be bonded to each other to form a ring with the sulfur atom.

Further, among R¹″ to R³″, at least one group represents an aryl group. Among R¹″ to R³″, two or more groups are preferably aryl groups, and it is particularly desirable that all of R¹″ to R³″ are aryl groups.

The aryl group for R¹″ to R³″ is not particularly limited. For example, an aryl group having 6 to 20 carbon atoms may be used in which some or all of the hydrogen atoms of the aryl group may or may not be substituted with alkyl groups, alkoxy groups, halogen atoms or hydroxyl groups,

The aryl group is preferably an aryl group having 6 to 10 carbon atoms because it can be synthesized at a low cost. Specific examples thereof include a phenyl group and naphthyl group.

The alkyl group, with which hydrogen atoms of the aryl group may be substituted, is preferably an alkyl group having 1 to 5 carbon atoms, and most preferably a methyl group, an ethyl group, a propyl group, an n-butyl group, or a tert-butyl group.

The alkoxy group, with which hydrogen atoms of the aryl group may be substituted, is preferably an alkoxy group having 1 to 5 carbon atoms, and most preferably a methoxy group, ethoxy group, n-propoxy group, iso-propoxy group, n-butoxy group or tert-butoxy group.

As the alkoxy group, with which hydrogen atoms of the aryl group may be substituted, an alkoxy group having 1 to 5 carbon atoms is preferable, and a methoxy group or an ethoxy group is particularly desirable.

The halogen atom, with which hydrogen atoms of the aryl group may be substituted, is preferably a fluorine atom.

The alkyl group for R¹″ to R³″ is not particularly limited and includes, for example, a linear, branched or cyclic alkyl group having 1 to 10 carbon atoms. In terms of achieving excellent resolution, the alkyl group preferably has 1 to 5 carbon atoms. Specific examples thereof include a methyl group, an ethyl group, an n-propyl group, an isopropyl group, an n-butyl group, an isobutyl group, an n-pentyl group, a cyclopentyl group, a hexyl group, a cyclohexyl group, a nonyl group, and a decanyl group, and a methyl group is most preferable because it is excellent in resolution and can be synthesized at a low cost.

It is particularly desirable that each of R¹″ to R³″ is a phenyl group or a naphthyl group.

When two of R¹″ to R³″ in formula (b-1) are bonded to each other to form a ring with the sulfur atom, it is preferable that the two of R¹″ to R³″ form a 3 to 10-membered ring including the sulfur atom, and it is particularly desirable that the two of R¹″ to R³″ form a 5 to 7-membered ring including the sulfur atom. When two of R¹″ to R³″ in formula (b-1) are bonded to each other to form a ring with the sulfur atom, the remaining one of R¹″ to R³″ is preferably an aryl group. As examples of the aryl group, the same as the above-mentioned aryl groups for R¹″ to R³″ can be exemplified.

R⁴″ represents a linear, branched or cyclic alkyl or fluorinated alkyl group.

The linear or branched alkyl group preferably has 1 to 10 carbon atoms, more preferably 1 to 8 carbon atoms, and most preferably 1 to 4 carbon atoms.

The cyclic alkyl group is preferably a cyclic group, as described for R¹″, having 4 to 15 carbon atoms, more preferably 4 to 10 carbon atoms, and most preferably 6 to 10 carbon atoms.

The fluorinated alkyl group preferably has 1 to 10 carbon atoms, more preferably 1 to 8 carbon atoms, and most preferably 1 to 4 carbon atoms. Further, the fluorination ratio of the fluorinated alkyl group (percentage of fluorine atoms within the alkyl group) is preferably from 10 to 100%, more preferably from 50 to 100%, and a fluorinated alkyl group in which all hydrogen atoms are substituted with fluorine atoms (i.e., a perfluoroalkyl group) is particularly desirable because the acid strength increases.

R⁴″ is most preferably a linear or cyclic alkyl group or fluorinated alkyl group.

In formula (b-2), R⁵″ and R⁶″ each independently represents an aryl group or alkyl group. At least one of R⁵″ and R⁶″ represents an aryl group. It is preferable that both of R⁵″ and R⁶″ represent an aryl group.

As the aryl group for R³″ and R⁶″, the same as the aryl groups for R¹″ to R³″ can be exemplified.

As the alkyl group for R⁵″ and R⁶″, the same as the alkyl groups for R¹″ to R³″ can be exemplified.

It is particularly desirable that both of R⁵″ and R⁶″ represents a phenyl group.

As R⁴″ in formula (b-2), the same as those mentioned above for R⁴″ in formula (b-1) can be exemplified.

Specific examples of suitable onium salt-based acid generators represented by formula (b-1) or (b-2) include diphenyliodonium trifluoromethanesulfonate or nonafluorobutanesulfonate; bis(4-tert-butylphenyl)iodonium trifluoromethanesulfonate or nonafluorobutanesulfonate; triphenylsulfonium trifluoromethanesulfonate, heptafluoropropanesulfonate or nonafluorobutanesulfonate; tri(4-methylphenyl)sulfonium trifluoromethanesulfonate, heptafluoropropanesulfonate or nonafluorobutanesulfonate; dimethyl(4-hydroxynaphthyl)sulfonium trifluoromethanesulfonate, heptafluoropropanesulfonate or nonafluorobutanesulfonate; monophenyldimethylsulfonium trifluoromethanesulfonate, heptafluoropropanesulfonate or nonafluorobutanesulfonate; diphenylmonomethylsulfonium trifluoromethanesulfonate, heptafluoropropanesulfonate or nonafluorobutanesulfonate; (4-methylphenyl)diphenylsulfonium trifluoromethanesulfonate, heptafluoropropanesulfonate or nonafluorobutanesulfonate; (4-methoxyphenyl)diphenylsulfonium trifluoromethanesulfonate, heptafluoropropanesulfonate or nonafluorobutanesulfonate; tri(4-tert-butyl)phenylsulfonium heptafluoropropanesulfonate or nonafluorobutanesulfonate; diphenyl(1-(4-methoxy)naphthyl)sulfonium trifluoromethanesulfonate, heptafluoropropanesulfonate or nonafluorobutanesulfonate; di(1-naphthyl)phenylsulfonium trifluoromethanesulfonate, heptafluoropropanesulfonate or nonafluorobutanesulfonate; 1-phenyltetrahydrothiophenium trifluoromethanesulfonate, heptafluoropropanesulfonate or nonafluorobutanesulfonate; 1-(4-methylphenyl)tetrahydrothiophenium trifluoromethanesulfonate, heptafluoropropanesulfonate or nonafluorobutanesulfonate; 1-(3,5-dimethyl-4-hydroxyphenyl)tetrahydrothiophenium trifluoromethanesulfonate, heptafluoropropanesulfonate or nonafluorobutanesulfonate; 1-(4-methoxynaphthalene-1-yl)tetrahydrothiophenium trifluoromethanesulfonate, heptafluoropropanesulfonate or nonafluorobutanesulfonate; 1-(4-ethoxynaphthalene-1-yl)tetrahydrothiophenium trifluoromethanesulfonate, heptafluoropropanesulfonate or nonafluorobutanesulfonate; 1-(4-n-butoxynaphthalene-1-yl)tetrahydrothiophenium trifluoromethanesulfonate, heptafluoropropanesulfonate or nonafluorobutanesulfonate; 1-phenyltetrahydrothiopyranium trifluoromethanesulfonate, heptafluoropropanesulfonate or nonafluorobutanesulfonate; 1-(4-hydroxyphenyl)tetrahydrothiopyranium trifluoromethanesulfonate, heptafluoropropanesulfonate or nonafluorobutanesulfonate; 1-(3,5-dimethyl-4-hydroxyphenyl)tetrahydrothiopyranium trifluoromethanesulfonate, heptafluoropropanesulfonate or nonafluorobutanesulfonate; and 1-(4-methylphenyl)tetrahydrothiopyranium trifluoromethanesulfonate, heptafluoropropanesulfonate or nonafluorobutanesulfonate. It is also possible to use onium salts in which the anion moiety of these onium salts are replaced by methanesulfonate, n-propane sulfonate, n-butanesulfonate, or n-octanesulfonate.

Further, onium salt-based acid generators in which the anion moiety in general formula (b-1) or (b-2) is replaced by an anion moiety represented by general formula (b-3) or (b-4) shown above (the cation moiety is the same as (b-1) or (b-2)) may be used.

In the present description, an oximesulfonate-based acid generator is a compound having at least one group represented by general formula (B-1) shown below, and has a feature of generating acid by irradiation. Such oximesulfonate-based acid generators are widely used for a chemically amplified resist composition, and can be appropriately selected.

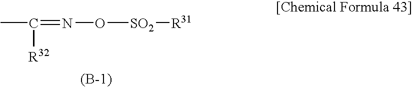

wherein R³¹ and R³² each independently represents an organic group.

The organic group for R³¹ and R³² refers to a group containing a carbon atom, and may include atoms other than carbon atoms (e.g., a hydrogen atom, an oxygen atom, a nitrogen atom, a sulfur atom, a halogen atom (such as a fluorine atom and a chlorine atom) and the like).

As the organic group for R³¹, a linear, branched, or cyclic alkyl group or aryl group is preferable. The alkyl group or the aryl group may have a substituent. The substituent is not particularly limited, and examples thereof include a fluorine atom and a linear, branched, or cyclic alkyl group having 1 to 6 carbon atoms. The expression “having a substituent” means that some or all of the hydrogen atoms of the alkyl group or the aryl group are substituted with substituents.

The alkyl group preferably has 1 to 20 carbon atoms, more preferably 1 to 10 carbon atoms, still more preferably 1 to 8 carbon atoms, still more preferably 1 to 6 carbon atoms, and most preferably 1 to 4 carbon atoms. As the alkyl group, a partially or completely halogenated alkyl group (hereinafter, sometimes referred to as a “halogenated alkyl group”) is particularly desirable. The “partially halogenated alkyl group” refers to an alkyl group in which some of the hydrogen atoms are substituted with halogen atoms, and the “completely halogenated alkyl group” refers to an alkyl group in which all of the hydrogen atoms are substituted with halogen atoms. Examples of the halogen atom include a fluorine atom, a chlorine atom, a bromine atom and an iodine atom, and a fluorine atom is particularly desirable. In other words, the halogenated alkyl group is preferably a fluorinated alkyl group.

The aryl group preferably has 4 to 20 carbon atoms, more preferably 4 to 10 carbon atoms, and most preferably 6 to 10 carbon atoms. As the aryl group, partially or completely halogenated aryl group is particularly desirable. The “partially halogenated aryl group” refers to an aryl group in which some of the hydrogen atoms are substituted with halogen atoms, and the “completely halogenated aryl group” refers to an aryl group in which all of hydrogen atoms are substituted with halogen atoms.

As R³³, an alkyl group of 1 to 4 carbon atoms which has no substituent or a fluorinated alkyl group of 1 to 4 carbon atoms is particularly desirable.

As the organic group for R³², a linear, branched, or cyclic alkyl group, aryl group, or cyano group is preferable. Examples of the alkyl group and the aryl group for R³² are the same as those of the alkyl group and the aryl group for R³¹.

As R³², a cyano group, an alkyl group of 1 to 8 carbon atoms having no substituent or a fluorinated alkyl group of 1 to 8 carbon atoms is particularly desirable.

Preferred examples of the oxime sulfonate-based acid generator include compounds represented by general formula (B-2) or (B-3) shown below.

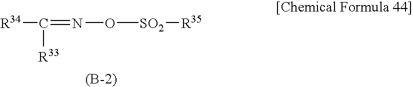

wherein R³³ represents a cyano group, an alkyl group having no substituent or a halogenated alkyl group; R³⁴ represents an aryl group; and R³⁵ represents an alkyl group having no substituent or a halogenated alkyl group.

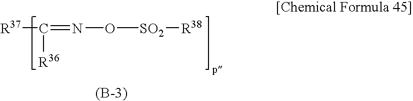

wherein R³⁶ represents a cyano group, an alkyl group having no substituent or a halogenated alkyl group; R³⁷ represents a divalent or trivalent aromatic hydrocarbon group; R³⁸ represents an alkyl group having no substituent or a halogenated alkyl group; and p″ represents 2 or 3.

In general formula (B-2), the alkyl group having no substituent or the halogenated alkyl group for R³³ preferably has 1 to 10 carbon atoms, more preferably 1 to 8 carbon atoms, and most preferably 1 to 6 carbon atoms.

As R³³, a halogenated alkyl group is preferable, and a fluorinated alkyl group is more preferable.

The fluorinated alkyl group for R³³ preferably has 50% or more of the hydrogen atoms thereof fluorinated, more preferably 70% or more, and most preferably 90% or more.

Examples of the aryl group for R³⁴ include groups in which one hydrogen atom has been removed from an aromatic hydrocarbon ring, such as a phenyl group, a biphenyl group, a fluorenyl group, a naphthyl group, an anthryl group, and a phenantryl group, and heteroaryl groups in which some of the carbon atoms constituting the ring(s) of these groups are substituted with hetero atoms such as an oxygen atom, a sulfur atom, and a nitrogen atom. Of these, a fluorenyl group is preferable.

The aryl group for R³⁴ may have a substituent such as an alkyl group of 1 to 10 carbon atoms, a halogenated alkyl group, or an alkoxy group. The alkyl group and halogenated alkyl group as the substituent preferably has 1 to 8 carbon atoms, and more preferably 1 to 4 carbon atoms. The halogenated alkyl group is preferably a fluorinated alkyl group.

The alkyl group having no substituent or the halogenated alkyl group for R³⁵ preferably has 1 to 10 carbon atoms, more preferably 1 to 8 carbon atoms, and most preferably 1 to 6 carbon atoms.

As R³⁵, a halogenated alkyl group is preferable, and a fluorinated alkyl group is more preferable.

In terms of enhancing the strength of the acid generated, the fluorinated alkyl group for R³⁵ preferably has 50% or more of the hydrogen atoms fluorinated, more preferably 70% or more, still more preferably 90% or more. A completely fluorinated alkyl group in which 100% of the hydrogen atoms are substituted with fluorine atoms is particularly desirable.

In general formula (B-3), the alkyl group having no substituent and the halogenated alkyl group for R³⁶ are the same as the alkyl group having no substituent and the halogenated alkyl group for R³³.

Examples of the divalent or trivalent aromatic hydrocarbon group for R³⁷ include groups in which one or two hydrogen atoms have been removed from the aryl group for R³⁴.

As the alkyl group having no substituent or the halogenated alkyl group for R³⁸, the same one as the alkyl group having no substituent or the halogenated alkyl group for R³⁸ can be used.

p″ is preferably 2.

Specific examples of suitable oxime sulfonate-based acid generators include α-(p-toluenesulfonyloxyimino)-benzyl cyanide, α-(p-chlorobenzenesulfonyloxyimino)-benzyl cyanide, α-(4-nitrobenzenesulfonyloxyimino)-benzyl cyanide, α-(4-nitro-2-trifluoromethylbenzenesulfonyloxyimino)-benzyl cyanide, α-(benzenesulfonyloxyimino)-4-chlorobenzyl cyanide, α-(benzenesulfonyloxyimino)-2,4-dichlorobenzyl cyanide, α-(benzenesulfonyloxyimino)-2,6-dichlorobenzyl cyanide, α-(benzenesulfonyloxyimino)-4-methoxybenzyl cyanide, α-(2-chlorobenzenesulfonyloxyimino)-4-methoxybenzyl cyanide, α-(benzenesulfonyloxyimino)-thien-2-yl acetonitrile, α-(4-dodecylbenzenesulfonyloxyimino)benzyl cyanide, α-[(p-toluenesulfonyloxyimino)-4-methoxyphenyl]acetonitrile, α-[(dodecylbenzenesulfonyloxyimino)-4-methoxyphenyl]acetonitrile, α-(tosyloxyimino)-4-thienyl cyanide, α-(methylsulfonyloxyimino)-1-cyclopentenyl acetonitrile, α-(methylsulfonyloxyimino)-1-cyclohexenyl acetonitrile, α-(methylsulfonyloxyimino)-1-cycloheptenyl acetonitrile, α-(methylsulfonyloxyimino)-1-cyclooctenyl acetonitrile, α-(trifluoromethylsulfonyloxyimino)-1-cyclopentenyl acetonitrile, α-(trifluoromethylsulfonyloxyimino)-cyclohexyl acetonitrile, α-(ethylsulfonyloxyimino)-ethyl acetonitrile, α-(propylsulfonyloxyimino)-propyl acetonitrile, α-(cyclohexylsulfonyloxyimino)-cyclopentyl acetonitrile, α-(cyclohexylsulfonyloxyimino)-cyclohexyl acetonitrile, α-(cyclohexylsulfonyloxyimino)-1-cyclopentenyl acetonitrile, α- (ethylsulfonyloxyimino)-1-cyclopentenyl acetonitrile, α-(isopropylsulfonyloxyimino)-1-cyclopentenyl acetonitrile, α-(n-butylsulfonyloxyimino)-1-cyclopentenyl acetonitrile, α-(ethylsulfonyloxyimino)-1-cyclohexenyl acetonitrile, α-(isopropylsulfonyloxyimino)-1-cyclohexenyl acetonitrile, α-(n-butylsulfonyloxyimino)-1-cyclohexenyl acetonitrile, α-(methylsulfonyloxyimino)-phenyl acetonitrile, α-(methylsulfonyloxyimino)-p-methoxyphenyl acetonitrile, α-(trifluoromethylsulfonyloxyimino)-phenyl acetonitrile, α-(trifluoromethylsulfonyloxyimino)-p-methoxyphenyl acetonitrile, α-(ethylsulfonyloxyimino)-p-methoxyphenyl acetonitrile, α-(propylsulfonyloxyimimo)-p-methylphenyl acetonitrile, and α-(methylsulfonyloxyimino)-p-bromophenyl acetonitrile.

Further, oxime sulfonate-based acid generators disclosed in Japanese Unexamined Patent Application, First Publication No, Hei 9-208554 (Chemical Formulas 18 and 19 shown in paragraphs [0012] to [0014]) and oxime sulfonate-based acid generators disclosed in International Application publication No. WO 2004/074242 (Examples 1 to 40 described at pages 65 to 85) may be preferably used.

Furthermore, as preferable examples, the following can be exemplified.

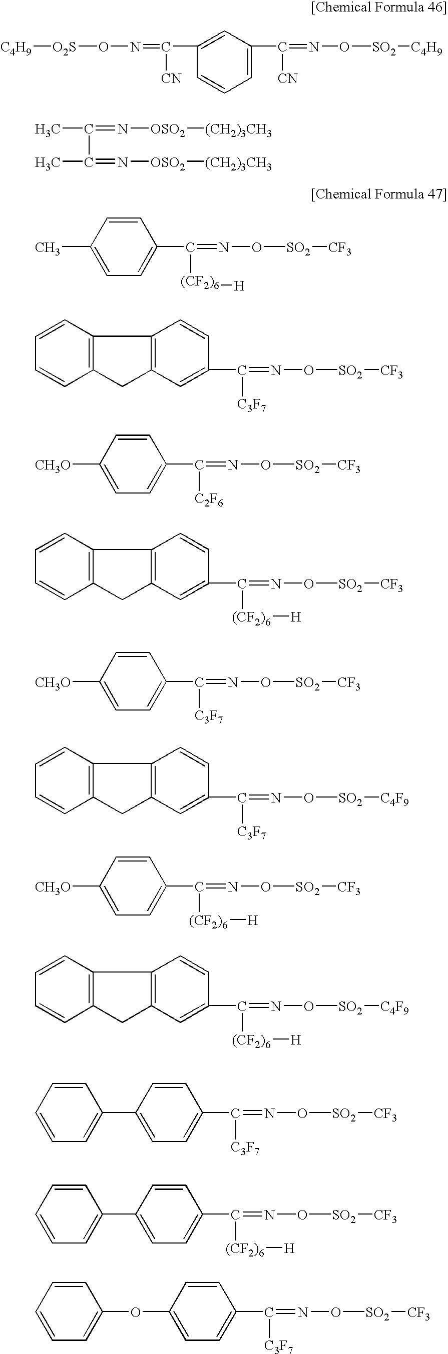

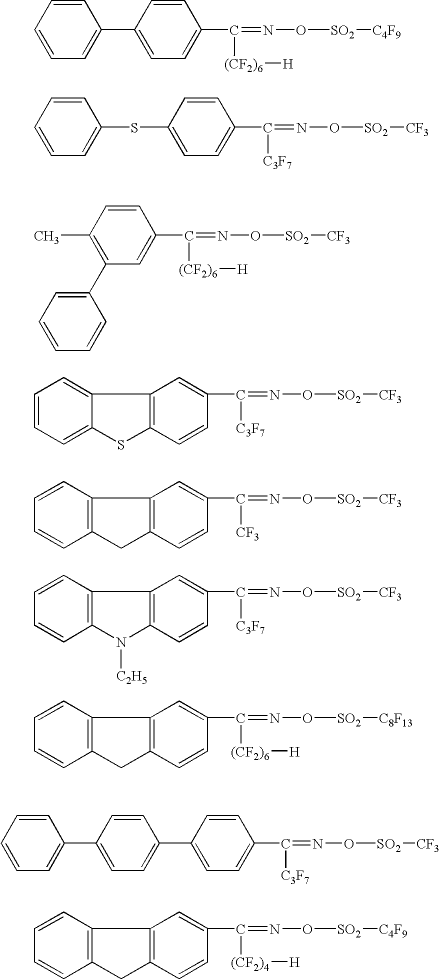

Among the above-exemplified compounds, the following 4 compounds are preferable.

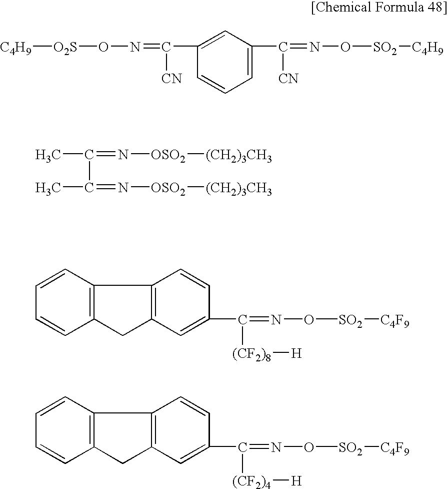

Of the aforementioned diazomethane-based acid generators, specific examples of suitable bisalkyl or bisaryl sulfonyl diazomethanes include bis(isopropylsulfonyl)diazomethane, bis(p-toluenesulfonyl)diazomethane, bis(1,1-dimethylethylsulfonyl)diazomethane, bis(cyclohexylsulfony)diazomethane, and bis(2,4-dimethylphenylsulfonyl)diazomethane.

Further, diazomethane-based acid generators disclosed in Japanese Unexamined Patent Application, First Publication No. Hei 11-035551, Japanese Unexamined Patent Application, First Publication No. Hei 11-035552 and Japanese Unexamined Patent Application, First Publication No. Hei 11-035573 may be preferably used.

Furthermore, as poly(bis-sulfonyl)diazomethanes, those disclosed in Japanese Unexamined Patent Application, First Publication No. Hei 11-322707, including 1,3-bis(phenylsulfonyldiazomethylsulfonyl)propane, 1,4-bis(phenylsulfonyldiazomethylsulfonyl)butane, 1,6-bis(phenylsulfonyldiazomethylsulfonyl)hexane, 1,10-bis(phenylsulfonyldiazomethylsulfonyl)decane, 1,2-bis(cyclohexylsulfonyldiazomethylsulfonyl)ethane, 1,3-bis(cyclohexylsulfonyldiazomethylsulfonyl)propane, 1,6-bis(cyclohexylsulfonyldiazomethylsulfonyl)hexane, and 1,10-bis(cyclohexylsulfonyldiazomethylsulfonyl)decane, may be exemplified.

As the component (B2), one type of acid generator may be used, or two or more types may be used in combination.

The total amount of the component (B) within the positive resist composition of the present invention, relative to 100 parts by weight of the component (A), is preferably 0.5 to 45 parts by weight, more preferably 1 to 40 parts by weight, still more preferably 5 to 30 parts by weight, and most preferably 10 to 25 parts by weight. When the amount of the component (B) is within the above-mentioned range, formation of a resist pattern can be satisfactorily performed. Further, by virtue of the above-mentioned range, a uniform solution can be obtained and the storage stability becomes satisfactory.

<Component (D)>

In the positive resist composition of the present invention, for improving the resist pattern shape and the post exposure stability of the latent image formed by the pattern-wise exposure of the resist layer, it is preferable to further include a nitrogen-containing organic compound (D) (hereafter referred to as the component (D)) as an optional component.

A multitude of these components (D) have already been proposed, and any of these known compounds may be used, although an aliphatic amine, and particularly a secondary aliphatic amine or tertiary aliphatic amine is preferable. In the present description and claims, the term “aliphatic” is a relative concept used in relation to the term “aromatic”, and defines a group or compound that has no aromaticity.

The term “aliphatic cyclic group” refers to a monocyclic group or polycyclic group that has no aromaticity. An aliphatic amine is an amine having one or more aliphatic groups, and the aliphatic groups preferably have 1 to 12 carbon atoms.

Examples of these aliphatic amines include amines in which at least one hydrogen atom of ammonia (NH₃) has been substituted with an alkyl group or hydroxyalkyl group of no more than 12 carbon atoms (i.e., alkylamines or alkylalcoholamines), and cyclic amines.

Specific examples of alkylamines and alkylalcoholamines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-pentylamine, tri-n-hexylamine, tri-n-heptylamine, tri-n-octylamine, tri-n-nonylamine, tri-n-decanylamine, and tri-n-dodecylamine; and alkyl alcohol amines such as diethanolamine, triethanolamine, diisopropanolamine, triisopropanolamine, di-n-octanolamine, and tri-n-octanolamine. Among these, trialkylamines of 5 to 10 carbon atoms are preferable, and tri-n-pentylamine is particularly desirable,

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine).

Specific examples of the aliphatic monocyclic amine include piperidine, and piperazine.

The aliphatic polycyclic amine preferably has 6 to 10 carbon atoms, and specific examples thereof include 1,5-diazabicyclo[4.3.0]-5-nonene, 1,8-diazabicyclo[5.4.0]-7-undecene, hexamethylenetetramine, and 1,4-diazabicyclo[2.2.2]octane.

These compounds can be used either alone, or in combinations of two or more different compounds.

In the present invention, as the component (D), it is preferable to use a trialkylamine of 5 to 10 carbon atoms.

The component (D) is typically used in an amount within a range from 0.01 to 5.0 parts by weight, relative to 100 parts by weight of the component (A).

<Optional component>

[Component (E)]

Furthermore, in the resist composition of the present invention, for preventing any deterioration in sensitivity, and improving the resist pattern shape and the post exposure stability of the latent image formed by the pattern-wise exposure of the resist layer, at least one compound (E) (hereafter referred to as the component (E)) selected from the group consisting of an organic carboxylic acid, or a phosphorus oxo acid or derivative thereof can be added.

Examples of suitable organic carboxylic acids include acetic acid, malonic acid, citric acid, malic acid, succinic acid, benzoic acid, and salicylic acid.

Examples of phosphorus oxo acids or derivatives thereof include phosphoric acid, phosphoric acid and phosphide acid. Among these, phosphonic acid is particularly desirable.

Examples of oxo acid derivatives include esters in which a hydrogen atom within the above-mentioned oxo acids is substituted with a hydrocarbon group. Examples of the hydrocarbon group include an alkyl group of 1 to 5 carbon atoms and an aryl group of 6 to 15 carbon atoms.

Examples of phosphoric acid derivatives include phosphoric acid esters such as di-n-butyl phosphate and diphenyl phosphate.

Examples of phosphonic acid derivatives include phosphonic acid esters such as dimethyl phosphonate, di-n-butyl phosphonate, phenylphosphonic acid, diphenyl phosphonate and dibenzyl phosphonate.

Examples of phosphinic acid derivatives include phosphinic acid esters such as phenylphosphinic acid.

As the component (E), one type may be used alone, or two or more types may be used in combination.

As the component (E), an organic carboxylic acid is preferable, and salicylic acid is particularly desirable.

The component (E) is typically used in an amount within a range from 0.01 to 5.0 parts by weight, relative to 100 parts by weight of the component (A).

If desired, other miscible additives can also be added to the positive resist composition of the present invention. Examples of such miscible additives include additive resins for improving the performance of the resist film, surfactants for improving the applicability, dissolution inhibitors, plasticizers, stabilizers, colorants, halation prevention, agents, and dyes.

<Component (S)>

The positive resist composition of the present invention can be prepared by dissolving the materials for the positive resist composition in an organic solvent (hereafter, frequently referred to as “component (S)”).

The component (S) may be any organic solvent which can dissolve the respective components to give a uniform solution, and any one or more kinds of organic solvents can be appropriately selected from those which have been conventionally known as solvents for a chemically amplified resist.

Examples thereof include lactones such as y-butyrolactone; ketones such as acetone, methyl ethyl ketone, cyclohexanone, methyl-n-pentyl ketone, methyl isopentyl ketone, and 2-heptanone; polyhydric alcohols, such as ethylene glycol, methylene glycol, propylene glycol and dipropylene glycol; compounds having an ester bond, such as ethylene glycol monoacetate, diethylene glycol monoacetate, propylene glycol monoacetate, and dipropylene glycol monoacetate, polyhydric alcohol derivatives including compounds having an ether bond, such as a monoalkylether (e.g., monomethylether, monoethylether, monopropylether or monobutylether) or monophenylether of any of these polyhydric alcohols or compounds having an ester bond (among these, propylene glycol monomethyl ether acetate (PGMEA) and propylene glycol monomethyl ether (PGME) are preferable); cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; and aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene and mesitylene.

These solvents can be used individually, or in combination as a mixed solvent.

Among these, propylene glycol monomethyl ether acetate (PGMEA), propylene glycol monomethyl ether (PGME), ethyl lactate (EL) and γ-butyrolactone are preferable.

Further, among the mixed solvents, a mixed solvent obtained by mixing PGMEA with a polar solvent is preferable. The mixing ratio (weight ratio) of the mixed solvent can be appropriately determined, taking into consideration the compatibility of the PGMEA with the polar solvent, but is preferably in the range of 1:9 to 9:1, more preferably from 2:8 to 8:2.

Specifically, when EL is mixed as the polar solvent, the PGMEA:EL weight ratio is preferably from 1:9 to 9:1, and more preferably from 2:8 to 8:2. Alternatively, when PGME is mixed as the polar solvent, the PGMEA:PGME is preferably from 1:9 to 9:1, more preferably from 2:8 to 8:2, and still more preferably 3:7 to 7:3.

Further, as the component (S), a mixed solvent of at least one of PGMEA and EL with γ-butyrolactone is also preferable. The mixing ratio (former:latter) of such a mixed solvent is preferably from 70:30 to 95:5.

The amount of the organic solvent is not particularly limited, and is appropriately adjusted to a concentration which enables coating of a coating solution to a substrate, depending on the thickness of the coating film. In general, the organic solvent is used in an amount such that the solid content of the resist composition becomes within the range from 2 to 20% by weight, and preferably from 5 to 15% by weight.

The positive resist composition of the present invention contains a novel compound preferable as an acid generator for resist compositions. According to the positive resist composition, a resist pattern with high resolution or excellent shape can be formed, which is especially required in formation of a fine resist pattern using EB or EUV as the exposure source.

The reasons for this have not yet been elucidated, but are presumed as follows.

The positive resist composition of the present invention contains the component (A) including a structural unit (a1) exhibiting alkali solubility and a structural unit (a2) having an acetal-type acid dissociable, dissolution inhibiting group on the side chain portion of acrylic acid. Especially, the acetal-type acid dissociable, dissolution inhibiting group within the structural unit (a2) exhibits a low activation energy in the deprotection reaction, and hence, it easily dissociates. Therefore, during exposure, the acid dissociable, dissolution inhibiting groups within the component (A) existing in the exposed portions are dissociated with a high ratio (deprotection ratio), and as a result, the alkali solubility of the exposed portions is significantly increased.

Further, the positive resist composition of the present invention contains the component (B) including an acid generator (B1) consisting of a compound represented by general formula (b1-1) above or an acid generator (B1′) consisting of a compound represented by general formula (b1-1′) above. As compared to acid generators having triphenylsulfonium (TPS) or the like as the cation moiety, the component (B1) and the component (B1′) exhibit excellent solubility in an organic solvent (resist solvent) for dissolving the respective components of the positive resist composition. Therefore, the component (B1) or the component (B1′) can be used in a large amount in the positive resist composition, and as a result, the concentration of the acid generator within the resist film is increased, and efficiency of acid generation is enhanced. Further, it is presumed that the component (B1) and the component (B1′) exhibit excellent dispersity in the resist film, and the component (B1) and the component (B1′) can be more uniformly dispersed within the resist film than conventional acid generators. As a result, it is presumed that acid generated from the component (B1) or the component (B1′) upon exposure can be more uniformly dispersed within the resist film than acid generated from conventional acid generators.

With respect to the component (B1), the acid generator (B11) represented by general formula (b1-1) in which Z is a hydrogen atom is per se soluble in an alkali developing solution. Therefore, it is presumed that a resist pattern with higher resolution can be formed.

On the other hand, with respect to the acid generator (B12) represented by general formula (b1-1) in which Z is a group represented by general formula (b1-1-1) (i.e., structure in which the phenolic hydroxyl group is protected with an oxycarbonyl group containing an acid dissociable group R⁴⁰¹), the acid dissociable groups are dissociated at exposed portions of the resist film, whereas the structure is not changed at unexposed portions. Therefore, it is presumed that the effect of inhibiting dissolution of unexposed portions in an alkali developing solution is enhanced, and as a result, a resist pattern with satisfactory head portion at the pattern top (pattern top is not round), high rectangularity and excellent shape can be formed.

Furthermore, it is presumed that the component (B1′) exhibits a high effect of inhibiting dissolution in an alkali developing solution, as compared to conventional acid generators. Therefore, when the positive resist composition of the present invention contains the component (B1′), it is presumed that the difference between the exposed portions and the unexposed portions in solubility in an alkali developing solution (dissolution contrast) becomes significantly large as compared to conventional resist compositions, and as a result, a resist pattern with high resolution can be formed.

<<Method of Forming a Resist Pattern>>

Next, the method of forming a resist pattern according to the second aspect of the present invention will be described.

The method of forming a resist pattern according to the present invention includes: applying a positive resist composition of the present invention to a substrate to form a resist film on the substrate; conducting exposure of the resist film; and alkali-developing the resist film to form a resist pattern.

More specifically, the method of forming a resist pattern according to the present invention can be performed, for example, as follows. Firstly, a positive resist composition of the present invention is applied onto a substrate using a spinner or the like, and a prebake (post applied bake (PAB)) is conducted under temperature conditions of 80 to 150° C. for 40 to 120 seconds, preferably 60 to 90 seconds to form a resist film. Then, for example, using an exposure apparatus or the like, the resist film is selectively exposed to EUV, an KrF excimer laser beam or the like through a desired mask pattern, or or direct patterning is conducted by direct irradiation with an electron beam without using a mask pattern. Thereafter, post exposure bake (PEB) Is conducted under temperature conditions of 80 to 150° C. for 40 to 120 seconds, preferably 60 to 90 seconds. Subsequently, developing is conducted using an alkali developing solution such as a 0.1to 10% by weight aqueous solution of tetramethylammonium hydroxide, preferably followed by rinsing with pure water, and drying. If desired, bake treatment (post, bake) can be conducted following the developing. In this manner, a resist pattern that is faithful to the mask pattern can be obtained.

The substrate is not specifically limited and a conventionally known substrate can be used. For example, substrates for electronic components, and such substrates having wiring patterns formed thereon can be exemplified. Specific examples of the material of the substrate include metals such as silicon wafer, copper, chromium, iron and aluminum; and glass. Suitable materials for the wiring pattern include copper, aluminum, nickel, and gold.

Further, as the substrate, any one of the above-exemplified substrates provided with an inorganic and/or organic film on the surface thereof may be used. As the inorganic film, an inorganic antireflection film (inorganic BARC) can be exemplified. As the organic film, an organic antireflection film (organic BARC) can be exemplified.

The wavelength to be used for exposure is not particularly limited and the exposure can be conducted using radiations such as ArF excimer laser, KrF excimer laser, F₂excimer laser, extreme ultraviolet rays (EUV), vacuum ultraviolet rays (VUV), electron beam (EB), X-rays, and soft X-rays. The positive resist composition of the present invention is effective to lithography using KrF excimer laser, ArF excimer laser, EB or EUV, more effective to lithography using EB or EUV, and particularly effective to lithography using EUV.

### EXAMPLES

As follows is a description of examples of the present invention, although the scope of the present invention is by no way limited by these examples.

<Resin Component (A)>

In Examples 1 to 4, Comparative Examples 1 and 2 and Reference Example 1, a resin (A)-1 synthesized by copolymerizing the following monomers (1) and (2) by a conventional dropwise polymerization method was used.

Specifically, the resin (A)-1 was synthesized as follows. Propylene glycol methyl ether acetate (PGMEA) was charged into a flask purged with nitrogen and equipped with an inlet for nitrogen, a stirrer, a condenser and a thermometer, and the temperature of the bath was elevated to 80° C. while stirring. Then, a monomeric PGMEA solution having charged therein 2,2′-azobisisobutyronitrile (AIBN) as a polymerization initiator, and monomer (1) and monomer (2) in a molar ratio of 3/1 was dropwise added to the flask at a constant rate over 6 hours using a dropping apparatus, and the temperature of the content of the flask was maintained at 80° C. for 1 hour. Then, the resulting reaction liquid was cooled to room temperature. Subsequently, the reaction liquid was dropwise added to methanol in an amount of about 30 times the amount of the reaction liquid while stirring, thereby obtaining a colorless precipitate. The obtained precipitate was separated by filtration, and the precipitate was washed in methanol in an amount of about 30 times the amount of monomers used in the polymerization. The resulting precipitate was separated by filtration, and dissolved in tetrahydrofuran (THF). Then, 80% by weight aqueous solution of hydrazine was dropwise added to the THF solution, and stirred at 25° C. for 1 hour. After the completion of the reaction, the resultant was dropwise added to excess amount of water to obtain a precipitate. The precipitate was separated by filtration, washed, and dried at 50° C. under reduced pressure for about 40 hours, thereby obtaining the resin (A)-1.

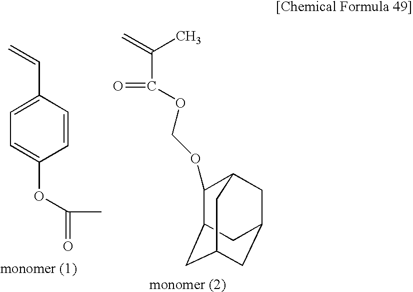

The structure of the resin (A)-1 is shown below.

The weight average molecular weight (Mw) and dispersity (Mw/Mn) of the resin (A)-1 are also shown, Mw and Mw/Mn were determined by the polystyrene equivalent value as measured by gel permeation chromatography (GPC).

Further, the compositional ratio was determined by carbon NMR. In the chemical formula, the subscript numerals on the brackets indicate the percentage (mol %) of the respective structural units within the copolymer.

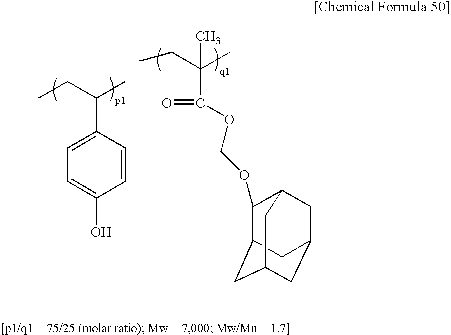

<Acid-Generator Component (B)>

In Examples 1 and 2, a compound (b1-51) and a compound (b1-81) synthesized by the following method were respectively used as acid generators.

[Synthesis of Compound (b1-51)]

1.99 g of diphosphorus pentaoxide was added to 120.2 g of methanesulfonic acid, and 5.86 g of 2,6-dimethylphenol was added thereto. The resulting solution was cooled down to 20° C. or lower in a water bath, and 8.01 g of dibenzothiophenoxide was gradually added thereto. Then, the water bath was removed, and a reaction was effected at room temperature for 14 hours. Thereafter, a mixed solution of 180.3 g of water and 180.3 g of dichloromethane was cooled down to 10° C. or lower, and the reaction liquid was dropwise added thereto gradually while maintaining the temperature of the reaction liquid at 25° C. or lower. Then, the aqueous phase was extracted from the reaction liquid by separation, and 13.54 g of sodium nonafluorobutane sulfonate was added thereto and stirred at room temperature for 1.5 hours. Then, 314.3 g of dichloromethane was added thereto and stirred, and the organic phase was extracted by separation. The organic phase was washed with 118.2 g of pure water until the organic phase became neutral, and the organic phase was extracted by separation. To the organic phase was added hexane (360.6 g ) as a poor solvent to obtain crystals. The obtained crystals were dried at 40° C. under reduced pressure, thereby obtaining 12.0 g of the objective compound (yield: 40%).

The obtained compound was analyzed by ¹H-NMR and 19F-NMR.

¹H-NMR (DMSO-d6,600 MHz): δ (ppm)=9.59 (br s, 1H, H^{g}), 8.49 (d, 2H, H^{a}), 8.25 (d, 2H, H^{d}), 7.95 (t, 2H, H^{c}), 7.74 (t, 2H, H^{b}), 7.20 (s, 2H, H^{o}), 2.14 (s, 6H, H^{f}).

¹⁹F-NMR (Acetone-d6, 376 MHz): δ (ppm)=−81.2, −414.6, −121.5, −126.0.

From the results shown above, it was confirmed that the obtained compound had the structure shown below.

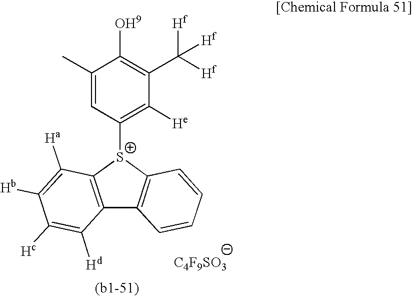

[Synthesis of Compound (b1-81)]

45.4 g of dichloromethane, 9.1 g of the compound (b1-51) and 0.4 g of N,N-dimethylamimopyridine were mixed together, 4.0 g of di-tert-butyl-dicarbonate was added to the resulting slurry, and a reaction was effected at 40° C. for 1 hour. Thereafter, the resultant was washed with diluted hydrochloric acid, followed by washing with water. Then, a dichloromethane solution of the resultant was dropwise added to 275 g of hexane, thereby obtaining 9.5 g of the objective compound in the form of a white powder (yield: 95%).

The obtained compound was analyzed by ¹H-NMR and ¹⁹F-NMR.

¹H-NMR (DMSO-d6, 400 MHz); δ(ppm)=8.53 (d, 2H, H^{o}), 8.36 (d, 2H, H^{d}), 7.97 (t, 2H, H^{o}), 7.77 (t, 2H, H^{b}), 7.44 (s, 2H, H^{o}), 2.11 (s, 6H, CH₃), 1.47(s, 9H, tBu).

¹⁹F-NMR (DMSO-d6, 376 MHz): δ(ppm)=−80.4, −114.8, −121.4, −125.7.

Further, as a result of a thermal analysis (TG-DTA), it was found that the peak decomposition temperature (Td) was 146° C., and the mass loss at that portion was 14.5%. This mass loss corresponds to the loss due to the elimination of the tert-butoxycarbonyl group.

From the results shown above, it was confirmed that the compound had a structure shown below.

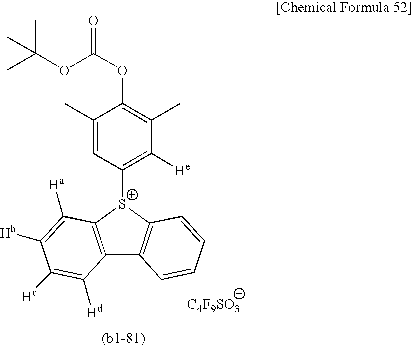

### Examples 1 and 2 and Comparative Example 1

The components shown in Table 1 were mixed together and dissolved to obtain positive resist compositions.

TABLE 1

| | Component (A) | Component (B) | Component (D) | Component (E) | Component (S) |
|---|---|---|---|---|---|
| Example 1 | (A)-1 | (B)-1 | (D)-1 | (E)-1 | (S)-1 |
| | [100] | [13.34] | [0.38] | [0.15] | [2400] |
| Example 2 | (A)-1 | (B)-2 | (D)-1 | (E)-1 | (S)-1 |
| | [100] | [15.52] | [0.38] | [0.15] | [2400] |
| Comparative | (A)-1 | (B)-3 | (D)-1 | (E)-1 | (S)-1 |
| Example 1 | [100] | [12.40] | [0.38] | [0.15] | [2400] |

In Table 1, the reference characters indicate the following. Further, the values in brackets [ ] indicate the amount (in terms of parts by weight) of the component added.

(B)-1: a compound represented by formula (b1-51) shown below

(B)-2: a compound represented by formula (b1-81) shown below

(B)-3: a compound represented by formula (b2-1) shown below

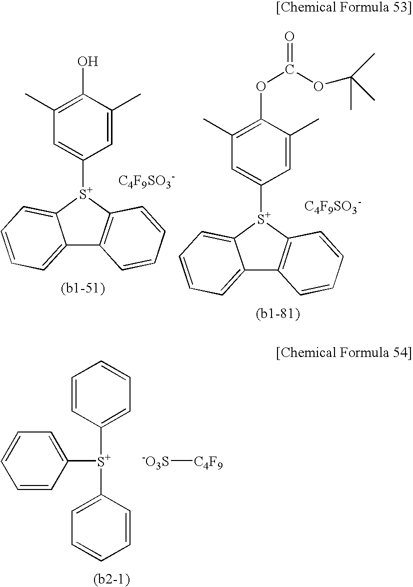

(D)-1: tri-n-octylamine

(E)-1: salicylic acid

(S)-1: a mixed solvent of PGMEA/PGME=6/4 (weight ratio)

Using the obtained positive resist compositions, resist films were formed. With respect to each of the resist films, the dissolution rate (thickness loss rate) of the unexposed portions after immersing the resist film in an alkali developing solution for a predetermined time was determined as follows.

[Measurement of Dissolution Rate (Thickness Loss Rate) of Unexposed Portions]

Each of the obtained positive resist compositions was uniformly applied onto an 8-inch silicon substrate, and prebake (post applied bake (PAB)) was conducted on a hot plate at 110° C. for 90 seconds. Then, a post exposure bake (PEB) treatment was conducted at 100° C. for 90 seconds, thereby forming a resist film having a film thickness of 1,500 nm.

The resist film was immersed in a 2.38% by weight aqueous solution of

tetramethylammonium hydroxide (TMAH) at 23° C. for 180 seconds, and the thickness loss was measured. The dissolution rate (thickness loss/immersion time) is shown in Table 2 as the “dissolution rate of unexposed portions (nm/s)”.

TABLE 2

| | Dissolution rate of |
|---|---|
| | unexposed portions |
| | (nm/s) |
| Example 1 | 0.179 |
| Example 2 | 0.044 |
| Comparative | 0.100 |
| Example 1 | |

From the results shown in Table 2 above, in Example 1, the dissolution rate of unexposed portions was high as compared to that in Comparative Example 1, and hence, it was confirmed that the acid generator (B)-1 contained in the positive resist composition of Example 1 exhibits a high effect of promoting dissolution in an alkali developing solution.

On the other hand, in Example 2, the dissolution rate of unexposed portions was low as compared to that in Comparative Example 1, and hence, it was confirmed that the acid generator (B)-2 contained in the positive resist composition of Example 2 exhibits a high effect of inhibiting dissolution in an alkali developing solution.

Using the obtained positive resist compositions, resolution and formation of a resist pattern was evaluated as follows.

<Formation of Resist Pattern>

Each of the positive resist compositions was uniformly applied onto an 8-inch silicon wafer that had its surface treated (at 90° C. for 36 seconds) with hexamethyldisilazane (HMDS), and was then prebaked (PAB) at a PAB temperature indicated in Tables 3 and 4 for 90 seconds, thereby forming a resist film with a film thickness of 100 nm.

The obtained resist film was subjected to direct patterning with an electron beam lithography apparatus (product name: HL-800D; manufactured by Hitachi Ltd.; accelerating voltage: 70 kV). Thereafter, a post exposure bake (PEB) treatment was conducted at a PEB temperature indicated in Tables 3 and 4 for 90 seconds, followed by development for 60 seconds at 23° C. in a 2.38% by weight aqueous solution of tetramethylammonium hydroxide (TMAH). Then, the resist was washed for 15 seconds with pure water, followed by drying by shaking, thereby forming a line and space (1:1) resist pattern (L/S pattern) with a line width of 100 nm and a pitch of 200 nm.

[Evaluation of Resolution]

In the formation of a resist pattern, the optimum exposure dose (Eop) (μC/cm²) for forming a L/S pattern having a line width of 100 nm and a pitch of200 nm was determined, and the critical resolution (nm) at the Eop was determined. The results are shown in Table 3.

TABLE 3

| | PAB | PEB | | |
|---|---|---|---|---|
| | temperature | temperature | Eop | Critical resolution |
| | (° C.) | (° C.) | (μC/cm²) | (nm) |
| Example 1 | 110 | 100 | 16.0 | 50 |
| Comparative | 110 | 100 | 19.0 | 70 |
| Example1 | | | | |

[Evaluation of Resist Pattern Shape]

The cross-sectional shape of the formed L/S pattern having a line width of 100 nm and a pitch of 200 nm was observed by a scanning electron microscope ((product name; S-9220, manufactured by Hitachi, Ltd,)), and the shape of the resist pattern was evaluated. The results are shown in Table 4.

TABLE 4

| | PAB | PEB | | |
|---|---|---|---|---|
| | temperature | temperature | Eop | |
| | (° C.) | (° C.) | (μC/cm²) | Shape of resist pattern |
| Example 2 | 110 | 100 | 24.0 | Satisfactory head portion at the |
| | | | | pattern top, and high rectangularity |
| Comparative | 110 | 100 | 19.0 | Round pattern top, and low |
| Example 1 | | | | rectangularity |

As shown by the results in Table 3, it was confirmed that the positive resist composition of Example 1 according to the present invention is capable of forming a resist pattern with high resolution, as compared to a resist pattern formed using the positive resist composition of Comparative Example 1.

Further, as shown by the results in Table 4, it was confirmed that the positive resist composition of Example 2 according to the present invention is capable of forming a resist pattern with low thickness loss, satisfactory head portion at the pattern top (the pattern top is not round), high rectangularity and excellent shape, as compared to a resist pattern formed using the positive resist composition of Comparative Example 1.

Therefore, it was confirmed that, according to the present invention, there are provided a positive resist composition containing a novel compound preferable as an acid generator for a resist composition, and a method of forming a resist pattern using the positive resist composition.

### Examples 3 and 4, Comparative Example 1 and Reference Example 1

The components shown in Table 5 were mixed together and dissolved to obtain positive resist compositions.

TABLE 5

| | Component (A) | Component (B) | Component (D) | Component (E) | Component (S) |
|---|---|---|---|---|---|
| Example 3 | (A)-1 | (B)-1′ | (D)-1 | (E)-1 | (S)-1 |
| | [100] | [12.34] | [0.38] | [0.15] | [2400] |
| Example 4 | (A)-1 | (B)-2′ | (D)-1 | (E)-1 | (S)-1 |
| | [100] | [12.89] | [0.38] | [0.15] | [2400] |
| Comparative | (A)-1 | (B)-3′ | (D)-1 | (E)-1 | (S)-1 |
| Example 2 | [100] | [12.40] | [0.38] | [0.15] | [2400] |
| Reference | (A)-1 | (B)-4′ | (D)-1 | (E)-1 | (S)-1 |
| Example 1 | [100] | [12.24] | [0.38] | [0.15] | [2400] |

In Table 5, the reference characters indicate the following. Further, the values in brackets [ ] indicate the amount (in terms of parts by weight) of the component added.

(B)-1′: a compound represented by formula (b1-01) shown below

(B)-2′: a compound represented by formula (b1-31) shown below

(B)-3′: a compound represented by formula (b2-1) shown below

(B)-4′: a compound represented by formula (b2-2) shown below

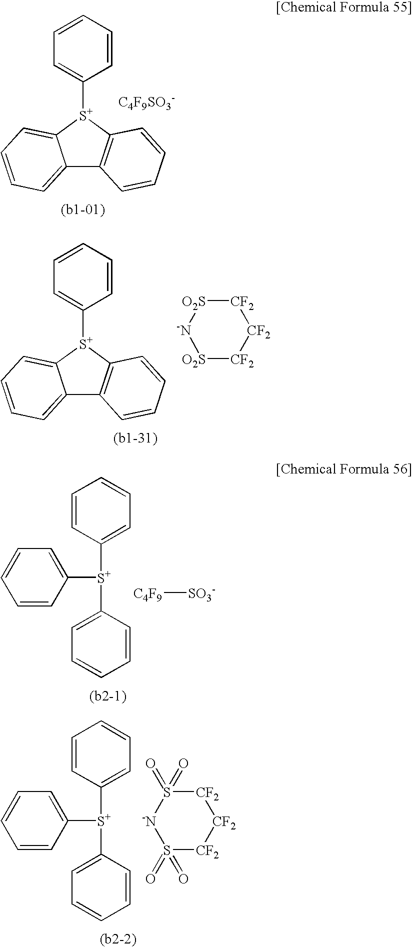

(D)-1; tri-n-octylamine

(E)-1: salicylic acid

(S)-1: a mixed solvent of PGMEA/PGME=6/4 (weight ratio)

Using the obtained positive resist compositions, resolution was evaluated as follows.

<Formation of Resist Pattern>

Using each, of the positive resist compositions, a resist film with a film thickness of 100 nm was formed in the same manner as in Examples 1 and 2 and Comparative Example 1, and a line and space (1:1) resist pattern (L/S pattern) with a line width of 100 nm and a pitch of200 nm was formed.

[Evaluation of Resolution]

The critical resolution (nm) at the optimum exposure dose (Eop) (μC/cm²) was determined in the same manner as in Example 1 and Comparative Example 1. The results are shown in Table 6.

TABLE 6

| | PAB | PEB | | |
|---|---|---|---|---|
| | temperature | temperature | Eop | Critical resolution |
| | (° C.) | (° C.) | (μC/cm²) | (nm) |
| Example 3 | 110 | 100 | 20.0 | 60 |
| Example 4 | 110 | 100 | 18.0 | 50 |
| Comparative | 110 | 100 | 19.0 | 70 |
| Example 2 | | | | |
| Reference | 110 | 100 | 20.0 | 70 |
| Example 1 | | | | |

As shown by the results in Table 6, it was confirmed that the positive resist compositions of Example 3 and 4 according to the present invention are capable of forming a resist pattern with high resolution, as compared to resist patterns formed using the positive resist compositions of Comparative Example 2 and Reference Example 1.

Therefore, it was confirmed that, according to the present invention, there are provided a positive resist composition exhibiting an excellent resolution, and a method of forming a resist pattern using the positive resist composition.

What is claimed is:

1. A positive resist composition comprising a resin component (A) which exhibits increased solubility in an alkali developing solution under action of acid and an acid-generator component (B) which generates acid upon exposure,
said resin component (A) comprising a structural unit (a1) derived from hydroxystyrene and a structural unit (a2) represented by general formula (a2-1) or (a2-2) shown below, and said acid-generator component (B) comprising an acid generator (B1) consisting of a compound represented by general formula (b1-1) shown below or an acid generator (B1′) consisting of a compound represented by general formula (b1-1′) shown below: 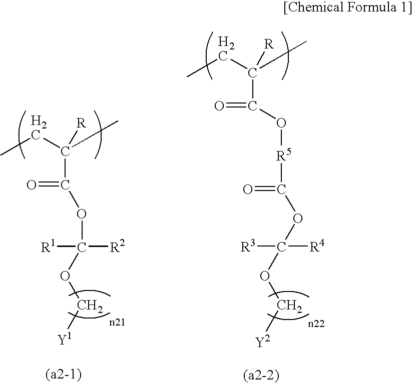
wherein in general formula (a2-1), R represents a hydrogen atom, a lower alkyl group of 1 to 5 carbon atoms or a halogenated lower alkyl group; R¹ and R² each independently represents a hydrogen atom or a lower alkyl group of 1 to 5 carbon atoms; Y¹ represents a lower alkyl group of 1 to 5 carbon atoms or a monovalent aliphatic cyclic group; and n₂₁ represents an integer of 0 to 3; and in general formula (a2-2), R is as defined above; R³ and R⁴ each independently represents a hydrogen atom or a lower alkyl group of 1 to 5 carbon atoms; R⁵ represents an alkylene group or a divalent aliphatic cyclic group; Y² represents a lower alkyl group of 1 to 5 carbon atoms or a monovalent aliphatic cyclic group; and n₂₂ represents an integer of 0 to 3; 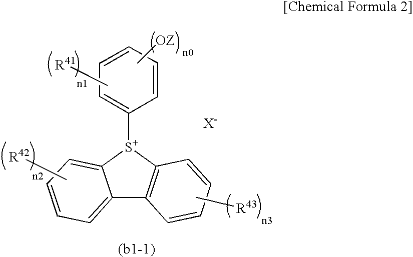
wherein Z represents a hydrogen atom or a group represented by general formula (b1-1-1) shown below; R⁴¹, R⁴² and R⁴³ each independently represents a halogen atom, a halogenated alkyl group, an alkyl group, an acetyl group, an alkoxy group, a carboxy group or a hydroxyalkyl group; no represents an integer of 1 to 3, and n₁ to n₃ each independently represents an integer of 0 to 3, with the proviso that n₀+n₁ is 5 or less; and X⁻ represents an anion; 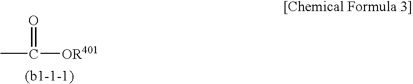
wherein R⁴⁰¹ represents an acid dissociable group; and 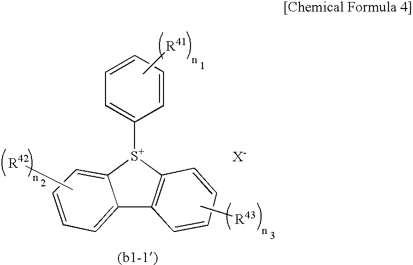
wherein R⁴¹, R⁴² and R⁴³ each, independently represents a halogen atom, a halogenated alkyl group, an alkyl group, an acetyl group, an alkoxy group, a carboxy group or a hydroxyalkyl group; n₁, n₂ and n₃ each independently represents an integer of 0 to 3; and X⁻ represents an anion.

2. The positive resist composition according to claim 1, wherein Z is a group represented by general formula (b1-1-1), and R⁴⁰¹ is an acid dissociable group represented by general formula (b1-1-10) shown below: 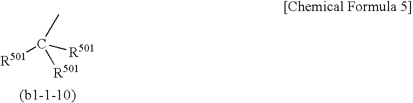
wherein the plurality of R⁵⁰¹ may be the same or different, and at least one R⁵⁰¹ represents a linear or branched alkyl group of 1 to 4 carbon atoms; and the remaining two R⁵⁰¹ each independently represents a linear or branched alkyl group of 1 to 4 carbon atoms or a monovalent aliphatic cyclic group of 4 to 20 carbon atoms, or the remaining two R⁵⁰¹ may be bonded to each other to form a divalent aliphatic cyclic group of 4 to 20 carbon atoms including the carbon atom to which the two R⁵⁰¹ are bonded.

3. The positive resist composition according to claim 1, wherein the amount of said acid generator (B1) or said acid generator (B1′) is 0.5 to 45 parts by weight, relative to 100 parts by weight of said resin component (A).

4. The positive resist composition according to claim 1, which further comprises a nitrogen-containing organic compound (D).

5. A method of forming a resist pattern, comprising: applying a resist composition of any one of claims 1 to 4 to a substrate to form a resist film on the substrate; conducting exposure of said resist film; and alkali-developing said resist film to form a resist pattern.
